(19) United States
(12) Patent Application Publication
(10) Pub. No.: US 2020/0003846 A1
(43) Pub. Date: Jan. 2, 2020

(54) MAGNETIC FIELD MEASURING DEVICE, MAGNETIC FIELD MEASUREMENT METHOD, AND RECORDING MEDIUM HAVING RECORDED THEREON MAGNETIC FIELD MEASUREMENT PROGRAM

(71) Applicant: Asahi Kasei Microdevices Corporation, Tokyo (JP)

(72) Inventors: Masanori MASUDA, Tokyo (JP); Kazuhiro ISHIDA, Tokyo (JP)

(21) Appl. No.: 16/458,210

(22) Filed: Jul. 1, 2019

(30) Foreign Application Priority Data
Jul. 2, 2018 (JP) 2018-126229
Apr. 26, 2019 (JP) 2019-085776

(51) Int. Cl. G01R 33/00; G01R 33/09

(52) U.S. Cl. CPC G01R 33/0041; G01R 33/093

(57) ABSTRACT

A magnetic field measuring device that can measure a weaker magnetic field is provided. The magnetic field measuring device provided includes: a sensor unit that has at least one magnetoresistive element; a magnetic field generating unit that generates a magnetic field to be applied to the sensor unit; a feedback current generating unit that supplies, based on an output voltage of the sensor unit, the magnetic field generating unit with a feedback current that generates a feedback magnetic field to diminish an input magnetic field to the sensor unit; a magnetic field measuring unit that outputs a measurement value corresponding to the feedback current; and a magnetic resetting unit that makes the magnetic field generating unit generate a reset magnetic field that magnetically saturates the magnetoresistive element.

The contents of the following Japanese patent application(s) are incorporated herein by reference:

2018-126229 filed in JP on Jul. 2, 2018

2019-085776 filed in JP on Apr. 26, 2019

### BACKGROUND

### 1. Technical Field

The present invention relates to a magnetic field measuring device, a magnetic field measurement method, and a recording medium having recorded thereon a magnetic field measurement program.

### 2. Related Art

There are known magnetic sensors in which one TMR (Tunnel Magneto-Resistance) element and three fixed resistors are used to form a bridge circuit, an electrical power for causing a current to flow through a magnetic field generating coil is generated based on an output voltage of the bridge circuit, and a magnetic field is applied to the TMR module by using the magnetic field generating coil (see Patent Literature 1, for example). In addition, there are known magnetic sensors in which one TMR element and three fixed resistors are used to form a bridge circuit, and a voltage to be applied to the bridge circuit is controlled based on an output voltage of the bridge circuit (see Patent Literature 2, for example).

Patent Literature 1: Japanese Patent Application Publication No. 2017-083173

Patent Literature 2: Japanese Patent Application Publication No. 2017-096627

### SUMMARY

If a magnetic field to be measured is a weak magnetic field, the behavior of a TMR element in response to the magnetic force exhibits a minor loop, and the magnetic resolution lowers as compared with the magnetic resolution that can be attained when a strong magnetic field is measured. However, for example in biomagnetic field measurement such as magnetocardiographic measurement, it is desired to realize a magnetic field measuring device that can measure a weaker magnetic field.

In order to overcome the drawbacks explained above, a first aspect of the present invention provides a magnetic field measuring device. The magnetic field measuring device may include a sensor unit that has at least one magnetoresistive element. The magnetic field measuring device may include a magnetic field generating unit that generates a magnetic field to be applied to the sensor unit. The magnetic field measuring device may include a feedback current generating unit that supplies, based on an output voltage of the sensor unit, the magnetic field generating unit with a feedback current that generates a feedback magnetic field to diminish an input magnetic field to the sensor unit. The magnetic field measuring device may include a magnetic field measuring unit that outputs a measurement value corresponding to the feedback current. The magnetic field measuring device may include a magnetic resetting unit that makes the magnetic field generating unit generate a reset magnetic field that magnetically saturates the magnetoresistive element.

In a reset phase, the magnetic resetting unit make the magnetic field generating unit generate the reset magnetic field, and in a measurement phase, the magnetic field measuring unit may output a measurement value corresponding to the feedback current generated for a measurement-target magnetic field.

The magnetic resetting unit may have a reset current supply unit that supplies a reset current to the magnetic field generating unit, and the reset current supply unit may supply the reset current to the magnetic field generating unit, and make the magnetic field generating unit generate the reset magnetic field.

The magnetic field measuring device may further include a switching unit that switches whether to or not to supply the feedback current to the magnetic field generating unit, and the reset current supply unit supplies the reset current to the magnetic field generating unit while the feedback current is not being supplied to the magnetic field generating unit.

The magnetic resetting unit may have a reference voltage generating unit that outputs a reference voltage, the feedback current generating unit may supply, to the magnetic field generating unit, the feedback current corresponding to a difference between the output voltage of the sensor unit and the reference voltage, and the reference voltage generating unit may change the reference voltage to be output, and make the magnetic field generating unit generate the reset magnetic field.

The reference voltage generating unit may have at least one variable resistor, and the reference voltage generating unit may change a resistance value of the variable resistor, and make the magnetic field generating unit generate the reset magnetic field.

An output voltage range of the reference voltage generating unit may be larger than an output voltage range of the sensor unit.

The magnetic field measuring device may further include an adjusting unit that uses the output voltage of the sensor unit to adjust the reference voltage.

The adjusting unit may adjust the reference voltage based on the feedback current.

The adjusting unit may adjust the reference voltage based on a difference between the output voltage of the sensor unit and the reference voltage.

After making the magnetic field generating unit generate the reset magnetic field to magnetically saturate the magnetoresistive element, the magnetic resetting unit may gradually weaken a strength of the reset magnetic field.

The magnetic field measuring unit may integrate measurement values obtained in a predetermined period, and output the integrated measurement values.

The magnetic field measuring device may further include a high-pass filter that allows passage therethrough of a high-frequency component of a measurement value output by the magnetic field measuring unit.

The feedback current generating unit may be formed by using two or more operational amplifiers.

The sensor unit may include a magnetic flux concentrating unit arranged adjacent to the magnetoresistive element, and the feedback current generating unit may be formed to surround the magnetoresistive element and the magnetic flux concentrating unit.

The magnetoresistive element may include a magnetization free layer, a non-magnetic layer, and a magnetization fixed layer that are stacked on a substrate in this order, and, when seen from above, the area of the magnetization fixed layer may be smaller than the area of the magnetization free layer, and a magnetosensitive area may be determined based on the area of the magnetization fixed layer.

The sensor unit may have a first magnetoresistive element and a second magnetoresistive element that are connected in series and have opposite polarity to each other, and a voltage across the first magnetoresistive element and the second magnetoresistive element may be output.

A second aspect of the present invention provides a magnetic field measurement method by which a magnetic field measuring device measures a magnetic field. The magnetic field measurement method may include supplying, by the magnetic field measuring device and based on an output voltage of a sensor unit having at least one magnetoresistive element, a magnetic field generating unit that generates a magnetic field to be applied to the sensor unit with a feedback current that generates a feedback magnetic field to diminish an input magnetic field to the sensor unit. The magnetic field measurement method may include outputting, by the magnetic field measuring device, a measurement corresponding to the feedback current. The magnetic field measurement method may include making, by the magnetic field measuring device, the magnetic field generating unit generate a reset magnetic field to magnetically saturate the magnetoresistive element.

A third aspect of the present invention provides a recording medium having recorded thereon a magnetic field measurement program. The magnetic field measurement program may be executed by a computer. The magnetic field measurement program may make the computer function as a feedback current generating unit that supplies, based on an output voltage of a sensor unit having at least one magnetoresistive element, a magnetic field generating unit that generates a magnetic field to be applied to the sensor unit with a feedback current that generates a feedback magnetic field to diminish an input magnetic field to the sensor unit. The magnetic field measurement program may make the computer function as a magnetic field measuring unit that outputs a measurement value corresponding to the feedback current. The magnetic field measurement program may make the computer function as a magnetic resetting unit that makes the magnetic field generating unit generate a reset magnetic field to magnetically saturate the magnetoresistive element.

The summary clause does not necessarily describe all necessary features of the embodiments of the present invention. The present invention may also be a sub-combination of the features described above.

### BRIEF DESCRIPTION OF THE DRAWINGS

FIG. 1 illustrates the configuration of a magnetic field measuring device 10 according to the present embodiment.

FIG. 2 illustrates a first exemplary flow of magnetic resetting in a reset phase performed by the magnetic field measuring device 10 according to the present embodiment.

FIG. 3 illustrates a magnetization curve of a typical magnetic substance.

FIG. 4 illustrates characteristics of voltage Vopen generated corresponding to an input magnetic field Bin to a sensor unit 110 in the magnetic field measuring device 10 according to the present embodiment.

FIG. 5 illustrates the configuration of the magnetic field measuring device 10 according to a variant of the present embodiment.

FIG. 6 illustrates an example of the magnetic field measuring device 10 according to a variant of the present embodiment in which a reference voltage generating unit 510 has at least one variable resistor.

FIG. 7 illustrates a second exemplary flow of magnetic resetting in a reset phase performed by the magnetic field measuring device 10 according to a variant of the present embodiment.

FIG. 8 illustrates an example of the magnetic field measuring device 10 according to a variant of the present embodiment in which an operating unit 140 has an adjusting unit 810.

FIG. 9 illustrates a first exemplary flow of magnetic operating point adjustment performed by the magnetic field measuring device 10 according to a variant of the present embodiment.

FIG. 10 illustrates characteristics of voltage Vopen generated corresponding to an input magnetic field Bin before and after magnetic operating point adjustment performed by the magnetic field measuring device 10 according to a variant of the present embodiment based on the flow illustrated in FIG. 9.

FIG. 11 illustrates a second exemplary flow of magnetic operating point adjustment performed by the magnetic field measuring device 10 according to a variant of the present embodiment.

FIG. 12 illustrates characteristics of voltage Vopen generated corresponding to an input magnetic field Bin before and after magnetic operating point adjustment performed by the magnetic field measuring device 10 according to a variant of the present embodiment based on the flow illustrated in FIG. 11.

FIG. 13 illustrates the configuration of the magnetic field measuring device 10 according to a variant of the present embodiment, the magnetic field measuring device 10 being provided with a first switch 1310.

FIG. 14 illustrates a third exemplary flow of magnetic operating point adjustment performed by the magnetic field measuring device 10 illustrated in FIG. 13.

FIG. 15 illustrates characteristics of voltage Vopen generated corresponding to an input magnetic field Bin before and after magnetic operating point adjustment performed by the magnetic field measuring device 10 illustrated in FIG. 13 based on the flow illustrated in FIG. 14.

FIG. 16 illustrates the configuration of the magnetic field measuring device 10 according to a variant of the present embodiment, the magnetic field measuring device 10 being provided with the first switch 1310 and an adjustment current generating unit 1610.

FIG. 17 illustrates a fourth exemplary flow of magnetic operating point adjustment performed by the magnetic field measuring device 10 illustrated in FIG. 16.

FIG. 18 illustrates characteristics of voltage Vopen generated corresponding to an input magnetic field Bin before and after magnetic operating point adjustment performed by the magnetic field measuring device 10 illustrated in FIG. 16 based on the flow illustrated in FIG. 17.

FIG. 19 illustrates characteristics of voltage Vopen generated corresponding to an adjustment current Iadjust used by the adjusting unit 810 in the magnetic field measuring device 10 illustrated in FIG. 16 for calculating voltage Vopen_adjust.

FIG. 20 illustrates dVopen/dIadjust characteristics used by the adjusting unit 810 in the magnetic field measuring device 10 illustrated in FIG. 16 for calculating the voltage Vopen_adjust.

FIG. 21 illustrates a flow for the magnetic field measuring device 10 according to the present embodiment to measure a magnetic field.

FIG. 22 illustrates the configuration of the magnetic field measuring device 10 according to a variant of the present embodiment, the magnetic field measuring device 10 being provided with a second switch 2160 and a high-pass filter 2170.

FIG. 23 illustrates the configuration of the magnetic field measuring device 10 according to a variant of the present embodiment, the magnetic field measuring device 10 being provided with a third operational amplifier 2180.

FIG. 24 illustrates a specific example of the sensor unit 110 according to the present embodiment.

FIG. 25 illustrates a magnetic flux distribution observed when a feedback magnetic field is generated to the sensor unit 110 according to the present specific example.

FIG. 26 illustrates an exemplary configuration of the sensor unit 110 according to the present specific example.

FIG. 27 shows an example of a computer 2200 in which aspects of the present invention may be wholly or partly embodied.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

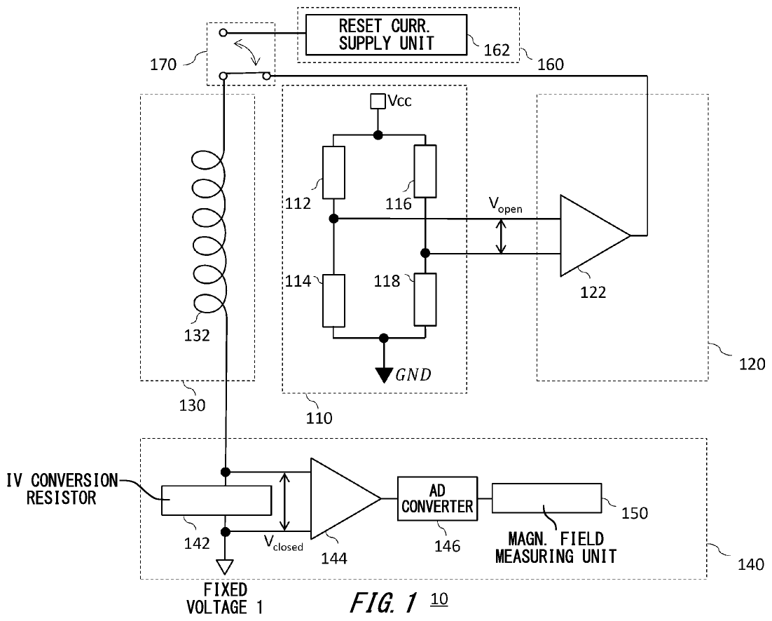

FIG. 1 illustrates the configuration of a magnetic field measuring device 10 according to the present embodiment. The magnetic field measuring device 10 uses a magnetoresistive element to measure a magnetic field generated by electrical activities of a living body (a human body, etc.) (referred to as a biomagnetic field). The magnetic field measuring device 10 performs a function of magnetically resetting a magnetoresistive element to be thereby able to measure a weaker magnetic field. The magnetic field measuring device 10 includes a sensor unit 110, a feedback current generating unit 120, a magnetic field generating unit 130, an operating unit 140, a magnetic resetting unit 160, and a switching unit 170. Note that the definition of magnetic resetting is described below.

The sensor unit 110 has at least one magnetoresistive element. In the present embodiment, for example, the sensor unit 110 has: a first magnetoresistive element 112 and a second magnetoresistive element 114 that are connected in series between power supply voltage Vcc and ground GND; and a third magnetoresistive element 116 and a fourth magnetoresistive element 118 that are connected in series between the power supply voltage Vcc and the ground GND. In the present embodiment, the sensor unit 110 outputs a voltage across the first magnetoresistive element 112 and the second magnetoresistive element 114, and a voltage across the third magnetoresistive element 116 and the fourth magnetoresistive element 118. In addition, the first magnetoresistive element 112, second magnetoresistive element 114, third magnetoresistive element 116, and fourth magnetoresistive element 118 constitute a bridge circuit. Instead of this, in the sensor unit 110, for example: at least any one of the first magnetoresistive element 112, the second magnetoresistive element 114, the third magnetoresistive element 116, and the fourth magnetoresistive element 118 may be constituted by a fixed resistor; any one pair of the pair of the first magnetoresistive element 112 and the second magnetoresistive element 114, and the pair of the third magnetoresistive element 116 and the fourth magnetoresistive element 118 may be constituted by a constant voltage source; and so on. There are various possible aspects in which the sensor unit outputs a voltage corresponding to a magnetic field input to at least one magnetoresistive element.

If the sensor unit 110 is configured to have at least the first magnetoresistive element 112 and the second magnetoresistive element 114 that are connected in series and have opposite polarity to each other, and to output a voltage across the first magnetoresistive element 112 and the second magnetoresistive element 114, an effect of reducing variations of characteristics such as offset or sensitivity characteristics due to temperature can be attained. Here, having opposite polarity means that the resistance of a magnetoresistive element increases, and the resistance of the other magnetoresistive elements decreases in response to magnetic fields input in the same direction. In the present embodiment illustrated, furthermore, the third magnetoresistive element 116 has opposite polarity to the first magnetoresistive element 112, and the fourth magnetoresistive element 118 has opposite polarity to the second magnetoresistive element 114, and the third magnetoresistive element 116 and the fourth magnetoresistive element 118 also have opposite polarity to each other, in addition to the first magnetoresistive element 112 and the second magnetoresistive element 114.

The first magnetoresistive element 112, second magnetoresistive element 114, third magnetoresistive element 116, and fourth magnetoresistive element 118 may be, for example, tunnel magneto-resistance (TMR) elements, giant magneto-resistance (GMR) elements, or the like.

The feedback current generating unit 120 supplies, based on an output voltage of the sensor unit 110, the magnetic field generating unit 130 with a feedback current that generates a feedback magnetic field to diminish an input magnetic field to the sensor unit 110. In the present embodiment, for example, the feedback current generating unit 120 has a first operational amplifier 122 that has two differential input terminals each connected to an output terminal of the sensor unit 110. Then, the first operational amplifier 122 generates a feedback current corresponding to the difference between output voltages of the sensor unit 110, and supplies the feedback current to the magnetic field generating unit 130. Here, the difference between output voltages of the sensor unit 110 is defined as Vopen.

The magnetic field generating unit 130 generates a magnetic field to be applied to the sensor unit 110. In the present embodiment, for example, the magnetic field generating unit 130 has a coil 132. If a feedback current is supplied from the feedback current generating unit 120, based on the supplied feedback current, the coil 132 generates a feedback magnetic field to be applied to each magnetoresistive element provided in the sensor unit 110. Here, the sensor unit 110 may be positioned to be enclosed by the coil 132.

The operating unit 140 has a current voltage conversion resistor 142, a second operational amplifier 144, an AD converter 146, and a magnetic field measuring unit 150, and performs various types of operations related to the magnetic field measuring device 10.

The current voltage conversion resistor 142 has one end connected to the magnetic field generating unit 130, and another end connected to a fixed voltage 1. The current voltage conversion resistor 142 converts a feedback current into a voltage, and generates, across its both ends, a voltage based on the feedback current (feedback currentx resistance value of the current voltage conversion resistor 142). Here, the voltage based on the feedback current generated by the current voltage conversion resistor 142 is defined as Vclosed.

The second operational amplifier 144 has a differential input terminal connected to both ends of the current voltage conversion resistor 142, and outputs a voltage VAMP corresponding to the voltage across both ends of the current voltage conversion resistor 142, that is, the voltage Vclosed.

The AD converter 146 is connected to the second operational amplifier 144, and converts, into a digital value VADC, the analog voltage value VAMP corresponding to the voltage Vclosed output by the second operational amplifier 144.

In a measurement phase, the magnetic field measuring unit 150 outputs a measurement corresponding to the feedback current generated for a measurement-target magnetic field. In the present embodiment, for example, the magnetic field measuring unit 150 is connected to the AD converter 146, and outputs a measurement value based on the digital value VADC that is obtained through conversion by the AD converter 146 and corresponds to the voltage Vclosed.

In a reset phase, the magnetic resetting unit 160 makes the magnetic field generating unit 130 generate a reset magnetic field to magnetically saturate each magnetoresistive element provided in the sensor unit 110. In the present embodiment, for example, the magnetic resetting unit 160 has a reset current supply unit 162 that supplies a reset current to the magnetic field generating unit 130. The reset current supply unit 162 supplies a reset current to the magnetic field generating unit 130, and makes the magnetic field generating unit 130 generate a reset magnetic field. Note that magnetic saturation means that a magnetic field with a certain strength is input to a magnetoresistive element, and output of the magnetoresistive element no longer varies in response to a magnetic field. A magnetic field at a level to magnetically saturate a magnetoresistive element in this manner is defined and used as a reset magnetic field, and a current that generates such a reset magnetic field is defined and used as a reset current.

The switching unit 170 is provided between the feedback current generating unit 120 and the magnetic field generating unit 130, and switches whether to or not to supply a feedback current generated by the feedback current generating unit 120 to the magnetic field generating unit 130. In addition, if a feedback current is not to be supplied to the magnetic field generating unit 130, the switching unit 170 makes the magnetic field generating unit 130 connected to the reset current supply unit 162. Then, the reset current supply unit 162 supplies a reset current to the magnetic field generating unit 130 while a feedback current is not being supplied to the magnetic field generating unit 130.

By using the magnetic field measuring device 10 according to the present embodiment, if a measurement-target magnetic field is input to the sensor unit 110, the feedback current generating unit 120 generates a feedback current corresponding to the difference between individual output voltages of the sensor unit 110 generated corresponding to the measurement-target magnetic field (that is, the voltage Vopen), and supplies the feedback current to the magnetic field generating unit 130. Then, according to the supplied feedback current, the magnetic field generating unit 130 generates a feedback magnetic field to cancel out the measurement-target magnetic field input to the sensor unit 110. Then, in a measurement phase, the magnetic field measuring unit 150 outputs a measurement value corresponding to the feedback current generated for the measurement-target magnetic field, specifically, a voltage value corresponding to the voltage Vclosed. Here, this series of control is defined as closed-loop control. Note that under the closed-loop control, control is performed such that the value of the voltage Vopen becomes 0, that is, a feedback magnetic field to cancel out an input magnetic field is generated.

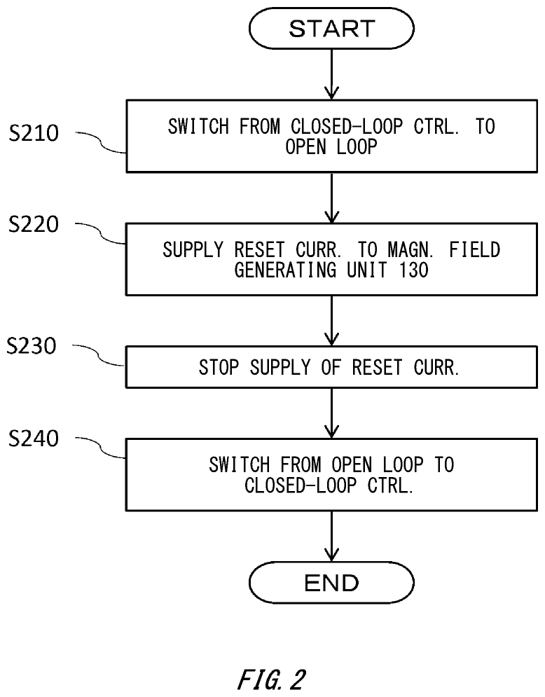

FIG. 2 illustrates a first exemplary flow of magnetic resetting in a reset phase performed by the magnetic field measuring device 10 according to the present embodiment. Here, the state where the closed-loop control is not being performed is defined as a open loop. At Step 210, the switching unit 170 switches the state of control from the closed-loop control to the state where a feedback current is not supplied to the magnetic field generating unit 130, that is, the open loop. In addition, the switching unit 170 makes the magnetic field generating unit 130 connected to the reset current supply unit 162.

Next, at Step 220, the reset current supply unit 162 supplies a reset current to the magnetic field generating unit 130, and makes the magnetic field generating unit 130 generate a reset magnetic field to magnetically saturate each magnetoresistive element provided in the sensor unit 110. Here, the reset current supply unit 162 may supply a current with a sufficient magnitude predetermined for magnetically saturating each magnetoresistive element provided in the sensor unit 110, and make the magnetic field generating unit 130 generate a reset magnetic field. Instead of this, while monitoring the output voltage of the sensor unit 110, the reset current supply unit 162 may gradually increase the strength of a supplied reset current until the output voltage of the sensor unit 110 reaches a value indicating that each magnetoresistive element is magnetically saturated, and make the magnetic field generating unit 130 generate a reset magnetic field. In order to be able to magnetically saturate a magnetoresistive element no matter how the magnetic field measuring device 10 is oriented, that is, regardless of the direction the geomagnetic field is applied, for example, the reset magnetic field may have at least the magnitude of a magnetic field that is required to magnetically saturate the magnetoresistive element in the absence of applied magnetic fields, plus the magnitude of the geomagnetic field.

Next, at Step 230, the reset current supply unit 162 stops supplying the reset current to the magnetic field generating unit 130. Here, after making the magnetic field generating unit 130 generate a reset magnetic field to magnetically saturate each magnetoresistive element, the reset current supply unit 162 may gradually weaken the magnitude of the reset current supplied to the magnetic field generating unit 130, and gradually weaken the strength of the reset magnetic field that the magnetic field generating unit 130 is caused to generate. Typically, if a magnetic field applied to a magnetoresistive element is intensified, its magnetic domain wall (the boundary between a magnetic domain and a magnetic domain) moves, next rotation of magnetization occurs in a magnetic domain, and eventually there emerges a single magnetic domain state where the entire region is occupied by a single magnetic domain. This corresponds to magnetic saturation. Then, if a magnetic field is weakened from the state of magnetic saturation, the magnetoresistive element generates magnetic domain walls with various magnetization directions so as to minimize the energy of the magnetoresistive element, and the magnetic domain wall moves along with the weakening of the magnetic field. By using the reset current supply unit 162 according to the present embodiment, at Step 230 after each magnetoresistive element is magnetically saturated, a reset magnetic field supplied to the magnetic field generating unit 130 is gradually weakened, and thereby the magnetoresistive elements can be caused to approach the same magnetization state always. Since a magnetoresistive element enters a similar state after each instance of magnetic resetting, fluctuations of the magnetization state of the magnetoresistive element after each instance of magnetic resetting can be reduced relatively.

Then, at Step 240, the switching unit 170 makes the magnetic field generating unit 130 connected to the feedback current generating unit 120, switches the state of control from the open loop to the feedback control, and ends the magnetic resetting process. Thereafter, in a measurement phase, under the closed-loop control, the magnetic field measuring unit 150 outputs a measurement value corresponding to a feedback current generated for a measurement-target magnetic field.

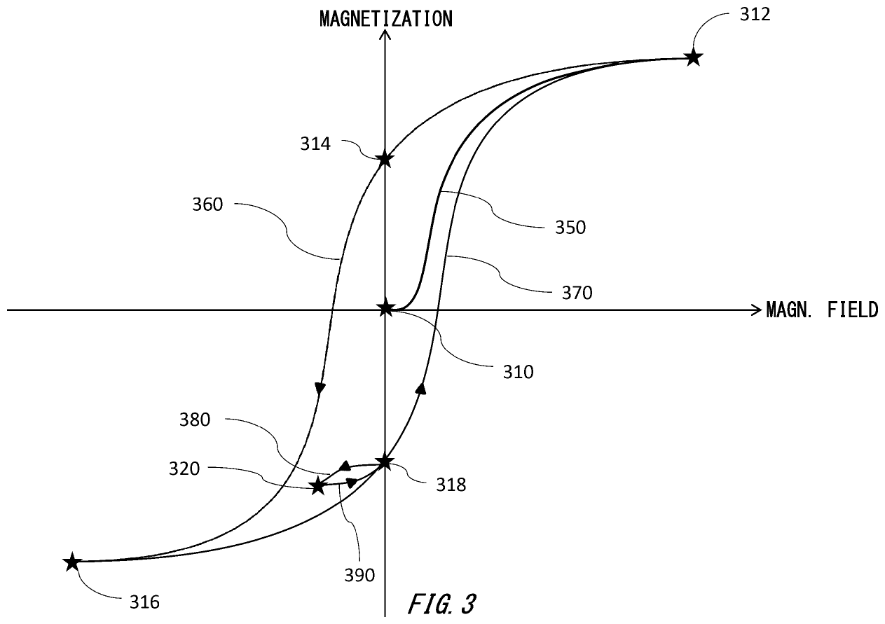

FIG. 3 illustrates a magnetization curve of a typical magnetic substance. In its initial magnetization state, the magnetic substance is not magnetized when there are no applied magnetic fields, as illustrated by a point 310. If, in this state, a magnetic field is applied toward the positive side, and is intensified, the magnetization increases as illustrated by a curve 350, and reaches a point 312. This curve 350 is called an initial magnetization curve. Upon reaching the point 312, the magnetization no longer changes even if the magnetic field applied toward the positive side is further intensified. At this time, the magnetic substance becomes magnetically saturated. If the magnetic field is weakened thereafter, the magnetization lowers not along the curve 350 but along a curve 360, and reaches a point 314. At the point 314, the magnetic substance is still magnetized even if there are no applied magnetic fields, and this is called residual magnetization. If a magnetic field is applied toward the negative side, and is further intensified, the magnetization decreases along the curve 360, and reaches a point 316. Upon reaching the point 316, the magnetization no longer changes even if the magnetic field applied toward the negative side is further intensified. At this time, the magnetic substance is again magnetically saturated. Thereafter, if a magnetic field is applied toward the positive side again, and is intensified, the magnetization increases not along the curve 360 but along a curve 370, and reaches the point 312 by way of a point 318. Magnetic substances typically have such magnetic hysteresis characteristics. Here, the largest loop consisting of the curve 360 and the curve 370 passing through the point 312 and the point 316 at which points the magnetic substance becomes magnetically saturated is called a major loop.

On the other hand, for example, if a magnetic field is applied toward the negative side in the state of the point 318, and is intensified, the magnetization lowers along a curve 380. If, in this state, a magnetic field is applied toward the positive side again at a point 320 before the magnetic substance is magnetically saturated, and is intensified, the magnetization increases not along the curve 380, but along a curve 390, and reaches the point 318. A loop consisting of, for example, the curve 380 and the curve 390 not passing through the points 312 and 316 at which points the magnetic substance becomes magnetically saturated in this manner is called a minor loop.

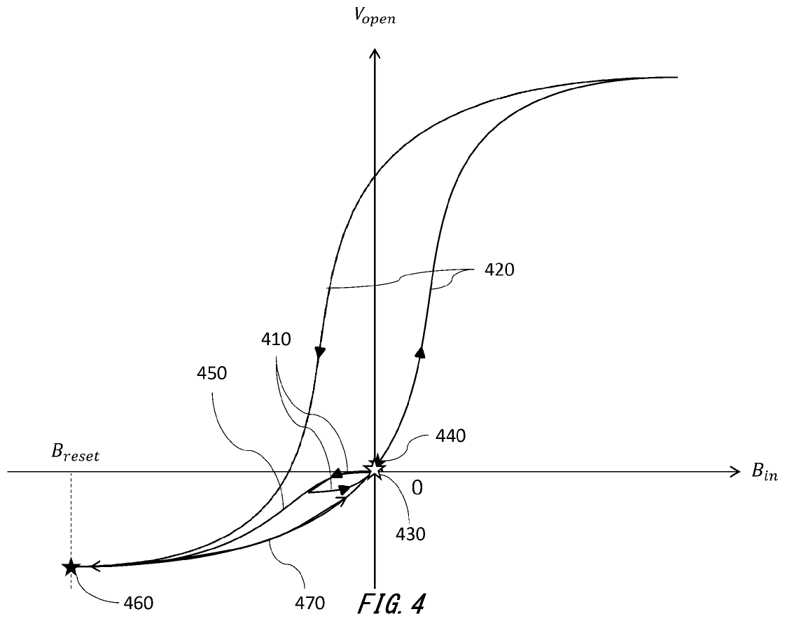

FIG. 4 illustrates characteristics of voltage Vopen generated corresponding to an input magnetic field Bin to the sensor unit 110 in the magnetic field measuring device 10 according to the present embodiment. In the present embodiment, characteristics of the voltage Vopen generated corresponding to the input magnetic field Bin to the sensor unit 110 are like the ones illustrated in this figure in accordance with the magnetic hysteresis characteristics of the first magnetoresistive element 112, second magnetoresistive element 114, third magnetoresistive element 116, and fourth magnetoresistive element 118 provided in the sensor unit 110. The symbol 410 indicates a minor loop, and the symbol 420 indicates a major loop.

If the magnetic field measuring device 10 according to the present embodiment performs measurement of a magnetic field under the closed-loop control before magnetic resetting is performed, it measures the magnetic field in the state where the magnetic operating point of each magnetoresistive element provided in the sensor unit 110 is at a point 430 on the minor loop 410. However, as a typical phenomenon of magnetic substances, each magnetoresistive element provided in the sensor unit 110, when operating on the minor loop, cannot attain a high magnetic sensitivity (the rate of change of the voltage Vopen in response to Bin) as compared with the case where it is operating on the major loop, and becomes unable to detect a weak measurement-target magnetic field. In view of this, in a magnetic resetting phase before a measurement phase, the magnetic field measuring device 10 in the present embodiment causes a transition of the magnetic operating point of each magnetoresistive element provided in the sensor unit 110 from the point 430 on the minor loop 410 to a point 440 on the major loop 420. Here, the magnetic operating point is defined as the total of magnetic fields input to magnetoresistive elements constituting the magnetic field measuring device 10 according to the present embodiment.

For example, in a magnetic resetting phase before a measurement phase, the magnetic field measuring device 10 according to the present embodiment magnetically resets each magnetoresistive element provided in the sensor unit 110 according to the flow illustrated in FIG. 2. Specifically, the switching unit 170 switches the state of control from the closed-loop control to the open loop, and the reset current supply unit 162 supplies a reset current to the magnetic field generating unit 130, and makes the magnetic field generating unit 130 generate a reset magnetic field Breset. At this time point, each magnetoresistive element provided in the sensor unit 110 becomes magnetically saturated, and the magnetic operating point transitions from the point 430 on the minor loop 410 to a point 460 on the major loop 420 along a curve 450. Then, the reset current supply unit 162 stops supplying the reset current. Then, the reset magnetic field Breset is no longer generated, and so the voltage Vopen becomes 0. Here, the magnetic operating point of each magnetoresistive element provided in the sensor unit 110 moves from the point 460 to the point 440 along a curve 470 constituting the major loop. Thereby, the magnetic field measuring device 10 according to the present embodiment can cause a transition of the magnetic operating point of each magnetoresistive element provided in the sensor unit 110 from the point 430 on the minor loop 410 to the point 440 on the major loop 420.

In a conventional magnetic sensor that uses a bridge circuit constituted by one TMR element and three fixed resistors, the magnetic operating point of the TMR element enters, in some cases, the minor loop where a high magnetic sensitivity cannot be attained. In contrast to this, the magnetic field measuring device 10 of the present embodiment can cause a transition of the magnetic operating point of each magnetoresistive element provided in the sensor unit 110 onto the major loop where a high magnetic sensitivity can be attained as compared with the minor loop, and can detect a weaker measurement-target magnetic field.

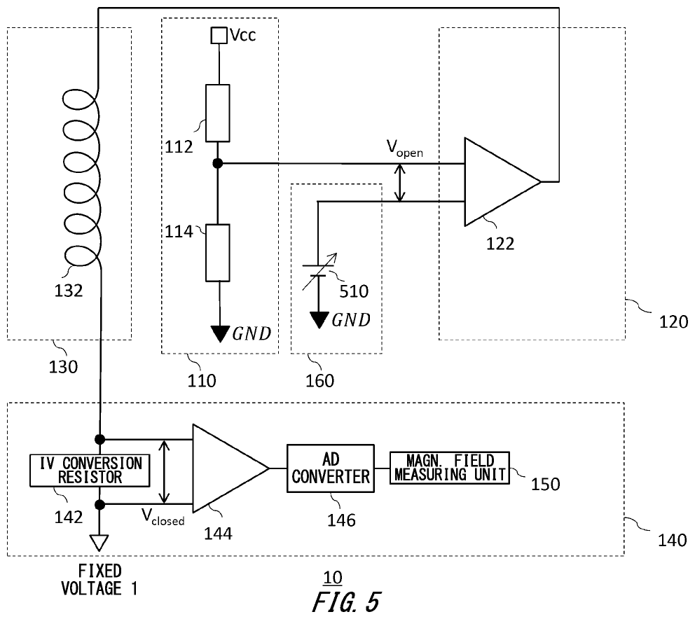

FIG. 5 illustrates the configuration of the magnetic field measuring device 10 according to a variant of the present embodiment. In FIG. 5, members having the same functions and configurations as those of members illustrated in FIG. 1 are given the same symbols, and also explanations related to matters other than differences therebetween are omitted hereinafter. The magnetic field measuring device 10 according to the present variant does not include a switching unit 170 unlike the magnetic field measuring device 10 illustrated in FIG. 1. In addition, the sensor unit 110 has the first magnetoresistive element 112 and the second magnetoresistive element 114 that are connected in series between the power supply voltage Vcc and the ground GND, and outputs a voltage across the first magnetoresistive element 112 and the second magnetoresistive element 114. In addition, instead of the reset current supply unit 162, the magnetic resetting unit 160 has a reference voltage generating unit 510 that outputs a reference voltage, and the feedback current generating unit 120 supplies, to the magnetic field generating unit 130, a feedback current corresponding to the difference between an output voltage of the sensor unit 110 and the reference voltage output by the reference voltage generating unit 510. Then, under the closed-loop control, the reference voltage generating unit 510 changes the reference voltage to be output, and makes the magnetic field generating unit 130 generate a reset magnetic field. Note that in this case, the difference between the output voltage of the sensor unit 110 and the reference voltage output by the reference voltage generating unit 510 is defined as Vopen. The magnetic field measuring device 10 according to the present variant allows elimination of delay resulting from processes required for switching of the state of control from the closed-loop control to the open loop when each magnetoresistive element is magnetically reset, since such switching is not required. In addition, since it is not required to use the reset current supply unit 162 separately from the reference voltage generating unit 510, the system can be simplified.

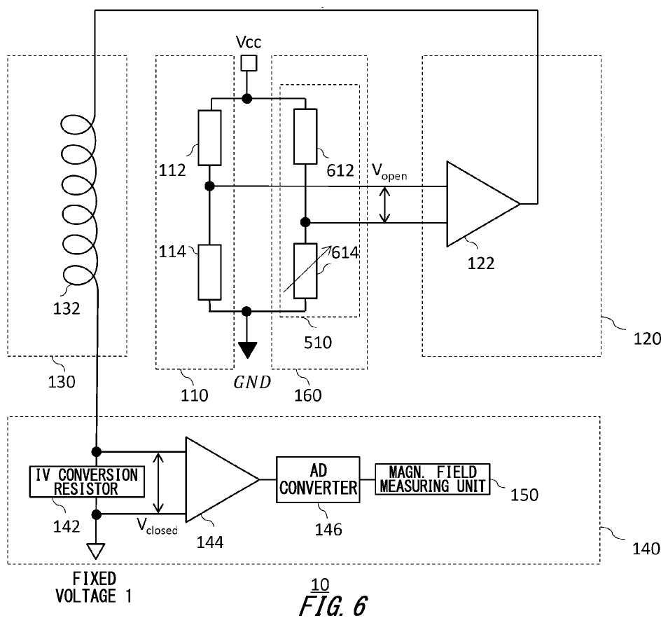

FIG. 6 illustrates an example of the magnetic field measuring device 10 according to a variant of the present embodiment in which the reference voltage generating unit 510 has at least one variable resistor. In FIG. 6, members having the same functions and configurations as those of members illustrated in FIG. 5 are given the same symbols, and also explanations related to matters other than differences therebetween are omitted hereinafter. As illustrated in this figure, the reference voltage generating unit 510 may have at least one variable resistor. For example, the reference voltage generating unit 510 may be configured to have a fixed resistor 612 and a variable resistor 614 connected in series between the power supply voltage Vcc and the ground GND, and output a voltage across the fixed resistor 612 and the variable resistor 614. In addition, the first magnetoresistive element 112, and second magnetoresistive element 114 provided in the sensor unit 110, and the fixed resistor 612 and variable resistor 614 provided in the reference voltage generating unit 510 may constitute a bridge circuit. Other than this, for example, the reference voltage generating unit 510 may have, as the fixed resistor 612, a magnetoresistive element having opposite polarity to the first magnetoresistive element 112, and have, as the variable resistor 614, a configuration in which a variable resistor and a magnetoresistive element having opposite polarity to the second magnetoresistive element 114 are connected in series. If the reference voltage generating unit 510 has a variable resistor, under the closed-loop control, the reference voltage generating unit 510 changes the resistance value of the variable resistor, and makes the magnetic field generating unit 130 generate a reset magnetic field.

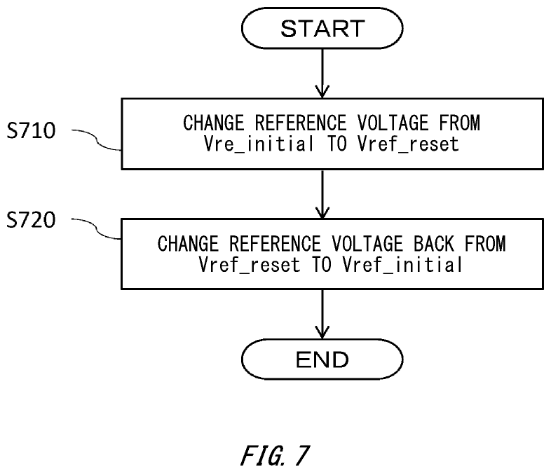

FIG. 7 illustrates a second exemplary flow of magnetic resetting in a reset phase performed by the magnetic field measuring device 10 according to a variant of the present embodiment. At Step 710, under the closed-loop control, the reference voltage generating unit 510 changes the reference voltage to be output from an initial reference voltage Vref initial to a reset reference voltage Vref reset. If the reference voltage generating unit 510 has at least one variable resistor as illustrated in FIG. 6, for example, the reference voltage generating unit 510 changes the resistance value of the variable resistor from an initial resistance value Rinitial to a reset resistance value Rreset, and changes the reference voltage to the reset reference voltage Vref reset. Then, the feedback current generating unit 120 generates a feedback current corresponding to the difference between the output voltage of the sensor unit 110 and the reset reference voltage Vref reset, that is, a reset current, and supplies this to the magnetic field generating unit 130. According to the supplied reset current, the magnetic field generating unit 130 generates a reset magnetic field to magnetically saturate each magnetoresistive element provided in the sensor unit 110. Here, the reference voltage generating unit 510 may change the reference voltage to a voltage with a sufficient magnitude predetermined for magnetically saturating each magnetoresistive element provided in the sensor unit 110, and make the magnetic field generating unit 130 generate a reset magnetic field. Instead of this, by monitoring the output of the sensor unit 110, the reference voltage generating unit 510 may change the reference voltage until the output voltage of the sensor unit 110 reaches a value indicating that each magnetoresistive element is magnetically saturated, and make the magnetic field generating unit 130 generate a reset magnetic field. Here, in order to attain the reference voltage for generating a reset magnetic field, preferably, the output voltage range of the reference voltage generating unit 510 is larger than the output voltage range of the sensor unit 110. Note that the output voltage range is defined as the difference between the maximum value that the output voltage can assume and the minimum value that the output voltage can assume.

Next, at Step 720, the reference voltage generating unit 510 changes the reference voltage to be output back from the reset reference voltage Vref reset to the initial reference voltage Vref initial, and ends the magnetic resetting process. Here, similar to Step 230 illustrated in FIG. 2, the reference voltage generating unit 510 may change the reference voltage output by the reference voltage generating unit back from the reset reference voltage Vref reset gradually to the initial reference voltage Vref initial, and gradually weaken the strength of the reset magnetic field that the magnetic field generating unit 130 is caused to generate. Thereafter, in a measurement phase, still under the closed-loop control, the magnetic field measuring unit 150 outputs a measurement value corresponding to a feedback current generated for a measurement-target magnetic field.

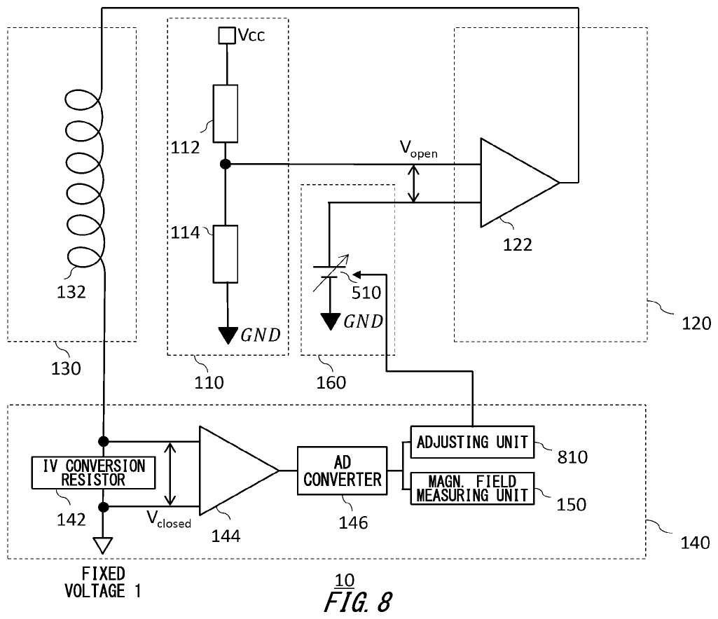

FIG. 8 illustrates an example of the magnetic field measuring device 10 according to a variant of the present embodiment in which the operating unit 140 has an adjusting unit 810. In FIG. 8, members having the same functions and configurations as those of members illustrated in FIG. 5 are given the same symbols, and also explanations related to matters other than differences therebetween are omitted hereinafter. The magnetic field measuring device 10 illustrated in this figure further has the adjusting unit 810 in addition to the configurations of the magnetic field measuring device 10 illustrated in FIG. 8. In an adjustment phase before a measurement phase, the adjusting unit 810 uses the output voltage of the sensor unit 110 to adjust the reference voltage output by the reference voltage generating unit 510. If the reference voltage generating unit 510 has at least one variable resistor as illustrated in FIG. 6, for example, the adjusting unit 810 changes the resistance value of the variable resistor, and adjusts the reference voltage.

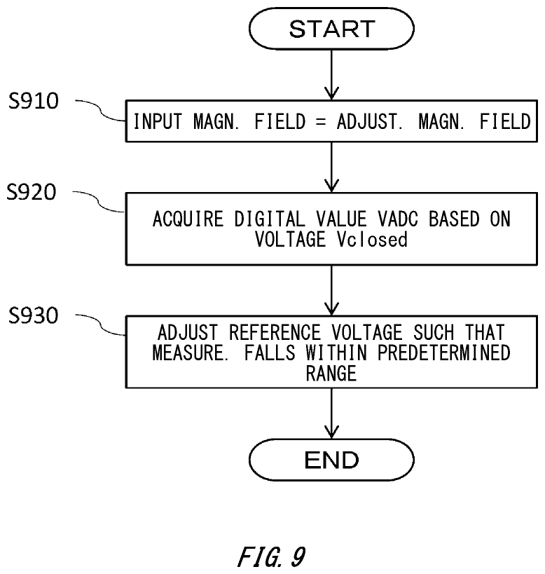

FIG. 9 illustrates a first exemplary flow of magnetic operating point adjustment performed by the magnetic field measuring device 10 according to a variant of the present embodiment. The magnetic operating point is defined as the total of magnetic fields input to magnetoresistive elements constituting the magnetic field measuring device 10 according to the present embodiment. At Step 910, for example, a measurer sets an input magnetic field to be input to the sensor unit 110 to an adjustment magnetic field having a value predetermined for performing magnetic operating point adjustment. Here, the adjustment magnetic field may have any value within a magnetic field range that the sensor unit 110 can perform magnetic detection. In the example explained below, there are no applied adjustment magnetic fields. If there are no applied adjustment magnetic fields, for example, a measurer places the magnetic field measuring device 10 the according to the present variant in a magnetic shield room or a portable magnetic shield box to thereby shield the magnetic field measuring device 10 from environmental magnetic fields such as the geomagnetic field such that there are no applied input magnetic fields input to the sensor unit 110.

Next, at Step 920, the adjusting unit 810 acquires the value of the digital value VADC that is based on the voltage Vclosed in the state where an adjustment magnetic field having a predetermined value is being input to the sensor unit 110.

Then, at Step 930, the adjusting unit 810 adjusts the reference voltage output by the reference voltage generating unit 510 based on a feedback current. In this flow, upon the sensor unit 110 receiving an adjustment magnetic field, the adjusting unit 810 adjusts the reference voltage output by the reference voltage generating unit 510 such that the digital value VADC that is based on a measurement value, for example, the voltage Vclosed, falls within a range of values predetermined according to the adjustment magnetic field, and the adjusting unit 810 ends the process. For example, the adjusting unit 810 adjusts the reference voltage output by the reference voltage generating unit 510 such that, for example, the value of the digital value VADC that is based on the voltage Vclosed becomes equal to or lower than a predetermined threshold so as to make the voltage Vclosed 0 if there are no applied adjustment magnetic fields input to the sensor unit 110. Note that if there is an applied adjustment magnetic field, the adjusting unit 810 adjusts the reference voltage output by the reference voltage generating unit 510 such that the voltage Vclosed becomes a value corresponding to the strength of the adjustment magnetic field. Note that in the closed loop, a voltage Vclosed and a voltage VAMP correspond to each other uniquely, and may be treated as equivalent physical quantities.

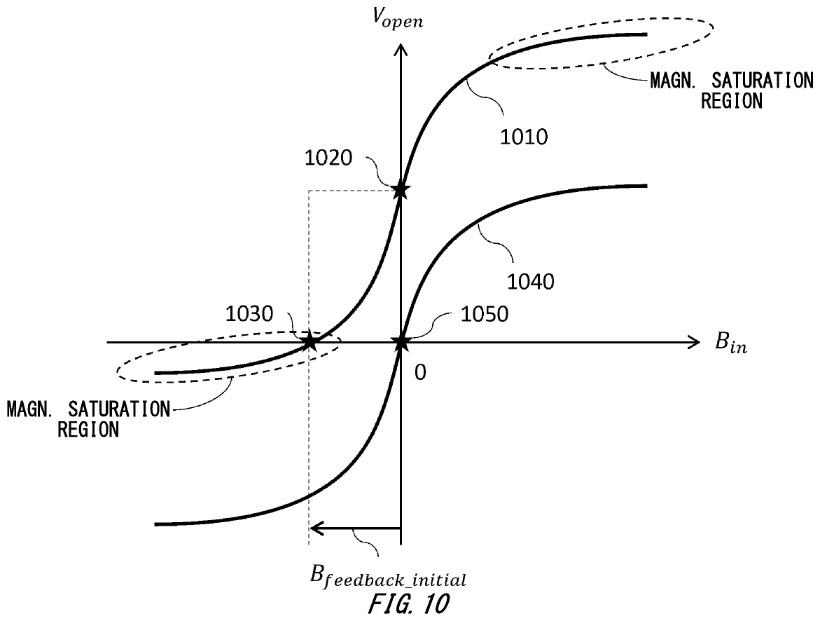

FIG. 10 illustrates characteristics of voltage Vopen generated corresponding to an input magnetic field Bin before and after magnetic operating point adjustment performed by the magnetic field measuring device 10 according to a variant of the present embodiment based on the flow illustrated in FIG. 9. Note that in the explanation of magnetic operating point adjustment, hysteresis characteristics are omitted for convenience of explanation. A curve 1010 illustrates characteristics of the voltage Vopen generated corresponding to the input magnetic field Bin to the sensor unit 110 before magnetic operating point adjustment based on the flow illustrated in FIG. 9. For example, if there are no applied input magnetic fields Bin to the sensor unit 110, the value of the voltage Vopen should be 0 provided that the output voltage of the sensor unit 110 and the reference voltage are ideally the same value. However, the output voltage of the sensor unit 110 and the reference voltage output by the reference voltage generating unit 510 do not necessarily become ideally the same value due to fluctuations in element formation processes of the first magnetoresistive element 112 and second magnetoresistive element 114 provided in the sensor unit 110, and the fixed resistor 612 and variable resistor 614 provided in the reference voltage generating unit 510, and the like, for example. As a result, even if there are no applied input magnetic fields Bin, the value of the voltage Vopen does not become 0, and may assume a finite value (defined as “Vinitial”) as illustrated by a point 1020, for example.

If the closed-loop control is performed in this state, the feedback current generating unit 120 generates a feedback current Ifeedback_initial corresponding to the voltage Vinitial, and supplies the feedback current Ifeedback_initial to the magnetic field generating unit 130. Then, based on this feedback current Ifeedback_initial, the magnetic field generating unit 130 generates the feedback magnetic field Bfeedback_initial so as to make the voltage Vopen 0. That is, due to the feedback magnetic field Bfeedback_initial, the voltage Vopen becomes 0, and the magnetic operating point transitions from the point 1020 to a point 1030. If the magnetic field measuring device 10 measures a measurement-target magnetic field in this state, the first magnetoresistive element 112 and the second magnetoresistive element 114 perform measurement of the magnetic field while the magnetic operating point is at the point 1030.

However, characteristics of the voltage Vopen generated corresponding to the input magnetic field Bin have magnetic saturation regions as illustrated in FIG. 10, in accordance with the magnetic saturation characteristics of the first magnetoresistive element 112 and second magnetoresistive element 114 provided in the sensor unit 110. Then, the first magnetoresistive element 112 and the second magnetoresistive element 114, if operated in the magnetic saturation regions or nearby regions, become unable to achieve a high magnetic sensitivity (the rate of change of the voltage Vopen in response to the magnetic field Bin), and to detect a weak measurement-target magnetic field. In view of this, in an adjustment phase before a measurement phase, the magnetic field measuring device 10 in the present embodiment adjusts the magnetic operating point of the first magnetoresistive element 112 and the second magnetoresistive element 114 to thereby make it possible for the first magnetoresistive element 112 and the second magnetoresistive element 114 to operate at a point where they can achieve a relatively high magnetic sensitivity, that is, a high magnetic resolution.

A curve 1040 illustrates characteristics of the voltage Vopen generated corresponding to the input magnetic field Bin to the sensor unit 110 after magnetic operating point adjustment based on the flow illustrated in FIG. 9. The magnetic field measuring device 10 according to the present embodiment performs magnetic operating point adjustment based on the flow illustrated in FIG. 9 to thereby be able to cause a transition of the operating point of the first magnetoresistive element 112 and the second magnetoresistive element 114 from the point 1030 to the point 1050. This point 1050 is a point where the voltage Vclosed becomes 0, that is, the feedback current becomes 0 if there are no applied input magnetic fields Bin, and, if the first magnetoresistive element 112 and the second magnetoresistive element 114 are operated at this point, the highest magnetic sensitivity can be achieved.

In a conventional magnetic sensor that uses a bridge circuit constituted by one TMR element and three fixed resistors, the magnetic operating point of the TMR element is positioned in a magnetic saturation region where the magnetic sensitivity is lowered due to fluctuations in element formation processes of the TMR element and the fixed resistors, and the like in some cases. In contrast to this, the magnetic field measuring device 10 of the present variant can cause a transition of the magnetic operating point of the first magnetoresistive element 112 and the second magnetoresistive element 114 to a point where the magnetic sensitivity is relatively high, and can detect a weaker measurement-target magnetic field as a signal.

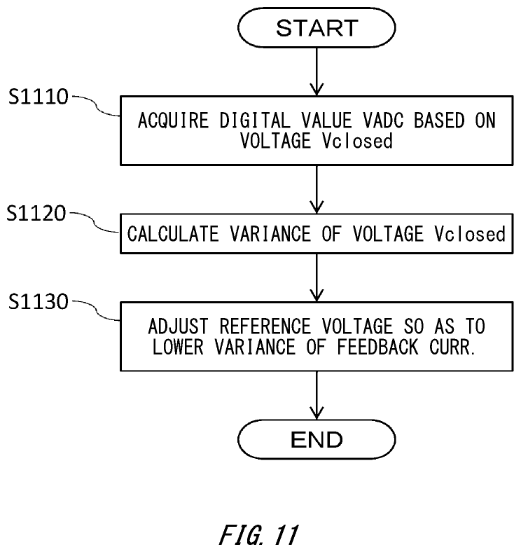

FIG. 11 illustrates a second exemplary flow of magnetic operating point adjustment performed by the magnetic field measuring device 10 according to a variant of the present embodiment. In the magnetic operating point adjustment in this flow, the input magnetic field Bin to be input to the sensor unit 110 needs not be set to an adjustment magnetic field having a predetermined value, unlike the magnetic operating point adjustment in the flow illustrated in FIG. 9. That is, for example, a measurer needs not to place the magnetic field measuring device 10 in a magnetic shield room or a portable magnetic shield box such that there are no applied input magnetic fields input to the sensor unit 110. At Step 1110, the adjusting unit 810 acquires the value of the digital value VADC that is based on the voltage Vclosed. Note that the input magnetic field input to the sensor unit 110 at this time point has not a predetermined known value, but an unknown value, as mentioned above.

Next, at Step 1120, the adjusting unit 810 calculates the variance of the voltage Vclosed acquired at Step 1110. Here, a variance indicates the magnitude of fluctuations of values that the voltage Vclosed can assume in a predetermined period. For example, the adjusting unit 810 may acquire values of the voltage Vclosed in a predetermined period, calculate their average value, square the difference between the value of each Vclosed and the average value, and take the average of the thus-obtained values to thereby calculate the variance of the voltage Vclosed.

Then, at Step 1130, the adjusting unit 810 adjusts the reference voltage output by the reference voltage generating unit 510 so as to lower the variance of the voltage Vclosed, and ends the process. For example, the adjusting unit 810 adjusts the reference voltage output by the reference voltage generating unit 510 such that the variance of the voltage Vclosed calculated at Step 1120 assumes the smallest value. Note that since the voltage Vclosed is a voltage obtained through conversion of a feedback current via the current voltage conversion resistor 142, minimizing the variance of the voltage Vclosed corresponds to minimizing the variance of the feedback current.

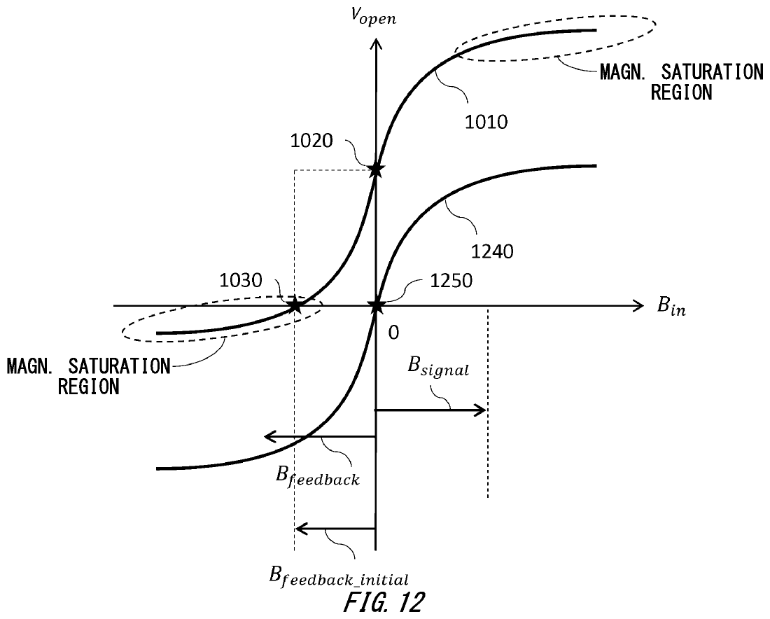

FIG. 12 illustrates characteristics of voltage Vopen generated corresponding to an input magnetic field Bin before and after magnetic operating point adjustment performed by the magnetic field measuring device 10 according to a variant of the present embodiment based on the flow illustrated in FIG. 11. Since explanations similar to those related to FIG. 10 apply to portions given the same symbols as those illustrated in FIG. 10, those explanations are omitted. A difference from FIG. 10 is that the input magnetic field Bin input to the sensor unit 110 has not a known value, but a finite unknown value (defined as “Bsignal”).

If the closed-loop control is performed in this state, the feedback current generating unit 120 generates the feedback current Ifeedback for cancelling out a magnetic field Bsignal in addition to the feedback current Ifeedback_initial corresponding to the voltage Vinitial, and supply them to the magnetic field generating unit 130. Then, based on these feedback currents, the magnetic field generating unit 130 generates the feedback magnetic field Bfeedback_initial so as to make the voltage Vopen 0, and also generates the feedback magnetic field Bfeedback so as to cancel out the magnetic field Bsignal. In this case also, the magnetic operating point of the first magnetoresistive element 112 and the second magnetoresistive element 114 is the point 1030, similar to FIG. 10. Here, the adjusting unit 810 adjusts the reference voltage output by the reference voltage generating unit 510 so as to adjust the magnetic operating point of the first magnetoresistive element 112 and the second magnetoresistive element 114 based on the feedback currents, but the adjusting unit 810 cannot distinguish between the feedback currents, Ifeedback_initial and Ifeedback.

In view of this, in the present embodiment, the adjusting unit 810 adjusts the reference voltage based on the variance of the voltage Vclosed. Typically, since as the magnetic operating point of a magnetoresistive element approaches a magnetic saturation point, the magnetic sensitivity lowers, it has characteristics that the ratio of fluctuations of output to the magnetic sensitivity (uncertainty of output) increases (that is, the signal noise ratio in magnetic detection lowers) as the magnetic operating point approaches a magnetic saturation point. Then, since in the present embodiment, the feedback currents generated by the feedback current generating unit 120 are based on the output voltage of the sensor unit 110 having the first magnetoresistive element 112 and the second magnetoresistive element 114, they reflect the signal noise ratio in magnetic detection by the first magnetoresistive element 112 and the second magnetoresistive element 114. For example, since as the magnetic operating point of the first magnetoresistive element 112 and the second magnetoresistive element 114 approaches a magnetic saturation point, the signal noise ratio lowers, fluctuations of the feedback currents increase following the lowering signal noise ratio. Accordingly, if the reference voltage is adjusted so as to reduce fluctuations of the feedback currents, it becomes possible to cause a transition of the magnetic operating point of the first magnetoresistive element 112 and the second magnetoresistive element 114 to a point farthest from a magnetic saturation point, that is, a point at which they can have the highest magnetic sensitivity. Utilizing this principle, the adjusting unit 810 adjusts the reference voltage output by the reference voltage generating unit 510 so as to reduce the variance of the voltage Vclosed reflecting the variance of the feedback currents, and causes a transition of the magnetic operating point of the first magnetoresistive element 112 and the second magnetoresistive element 114 to a point where they can have a relatively high magnetic sensitivity.

A curve 1240 illustrates characteristics of the voltage Vopen generated corresponding to the input magnetic field Bin to the sensor unit 110 after magnetic operating point adjustment based on the flow illustrated in FIG. 11. The magnetic field measuring device 10 according to the present variant performs magnetic operating point adjustment based on the flow illustrated in FIG. 11 to thereby be able to cause a transition of the magnetic operating point of the first magnetoresistive element 112 and the second magnetoresistive element 114 from the point 1030 to a point 1250. This point 1250 is a point where the variance of the voltage Vclosed becomes the smallest, that is, the variance of the feedback current becomes the smallest, and, if the first magnetoresistive element 112 and the second magnetoresistive element 114 are operated at this point, the highest magnetic sensitivity can be achieved.

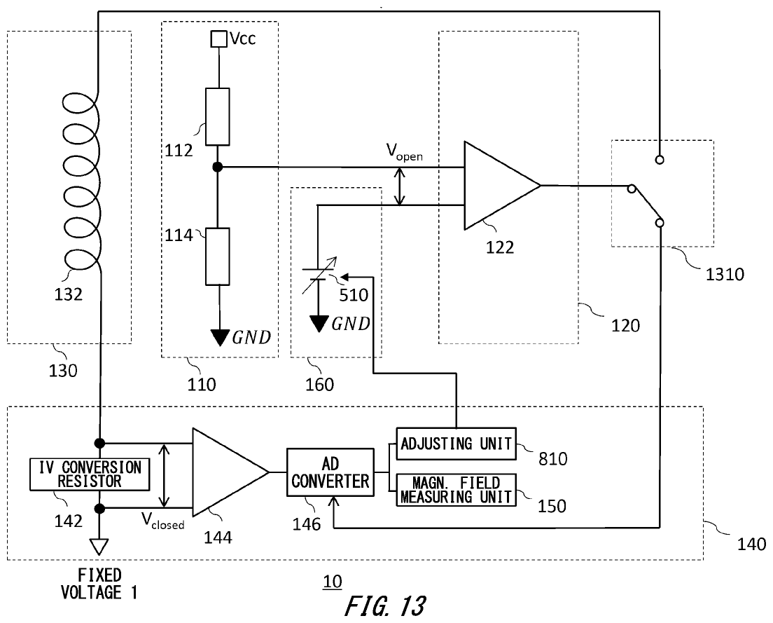

FIG. 13 illustrates the configuration of the magnetic field measuring device 10 according to a variant of the present embodiment, the magnetic field measuring device 10 being provided with a first switch 1310. In FIG. 13, members having the same functions and configurations as those of members illustrated in FIG. 8 are given the same symbols, and also explanations related to matters other than differences therebetween are omitted hereinafter. The magnetic field measuring device 10 illustrated in this figure further includes the first switch 1310 in addition to the configurations of the magnetic field measuring device 10 illustrated in FIG. 8. The first switch 1310 is provided between the feedback current generating unit 120 and the magnetic field generating unit 130, and can switch whether to or not to supply a feedback current generated by the feedback current generating unit 120 to the magnetic field generating unit 130. In addition, the first switch 1310 can supply output of the feedback current generating unit 120 to the AD converter 146 if a feedback current is not supplied to the magnetic field generating unit 130. In this case, the adjusting unit 810 uses the output voltage of the sensor unit 110 in the state where a feedback current is not being supplied to the magnetic field generating unit 130 to adjust the reference voltage output by the reference voltage generating unit 510.

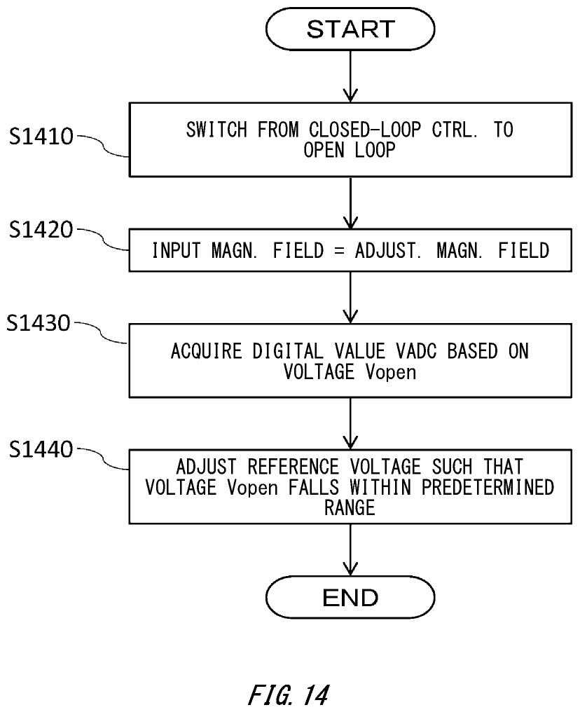

FIG. 14 illustrates a third exemplary flow of magnetic operating point adjustment performed by the magnetic field measuring device 10 illustrated in FIG. 13. At Step 1410, the first switch 1310 switches the state of control from the closed-loop control to the state where a feedback current is not supplied to the magnetic field generating unit 130, that is, the open loop. In addition, the first switch 1310 supplies output of the feedback current generating unit 120 to the AD converter 146.

At Step 1420, similar to step 910 illustrated in FIG. 9, for example, a measurer sets an input magnetic field to be input to the sensor unit 110 to an adjustment magnetic field having a value predetermined for performing magnetic operating point adjustment. Note that in this case also, preferably there are no applied adjustment magnetic fields. In the example explained below, there are no applied adjustment magnetic fields.

Next, at Step 1430, the adjusting unit 810 acquires the value of the voltage Vopen in the state where an adjustment magnetic field having a predetermined value is being input to the sensor unit 110. For example, through digital conversion of output of the feedback current generating unit 120 by the AD converter 146, the adjusting unit 810 acquires a digital value VADC that is based on the voltage Vopen. Note that in the open loop, a voltage Vopen and a digital value VADC correspond to each other uniquely, and may be treated as equivalent physical quantities.

Then, at Step 1440, upon the sensor unit 110 receiving an adjustment magnetic field while the feedback currents are not being supplied to the magnetic field generating unit 130, the adjusting unit 810 adjusts the reference voltage output by the reference voltage generating unit 510 such that the voltage Vopen which is the difference between the output voltage of the sensor unit 110 and the reference voltage output by the reference voltage generating unit 510 falls within a determined range in response to the adjustment magnetic field, and ends the process. For example, the adjusting unit 810 adjusts the reference voltage output by the reference voltage generating unit 510 such that, for example, the absolute value of the voltage Vopen becomes equal to or lower than a predetermined threshold so as to make the voltage Vopen 0 if there are no applied adjustment magnetic fields input to the sensor unit 110.

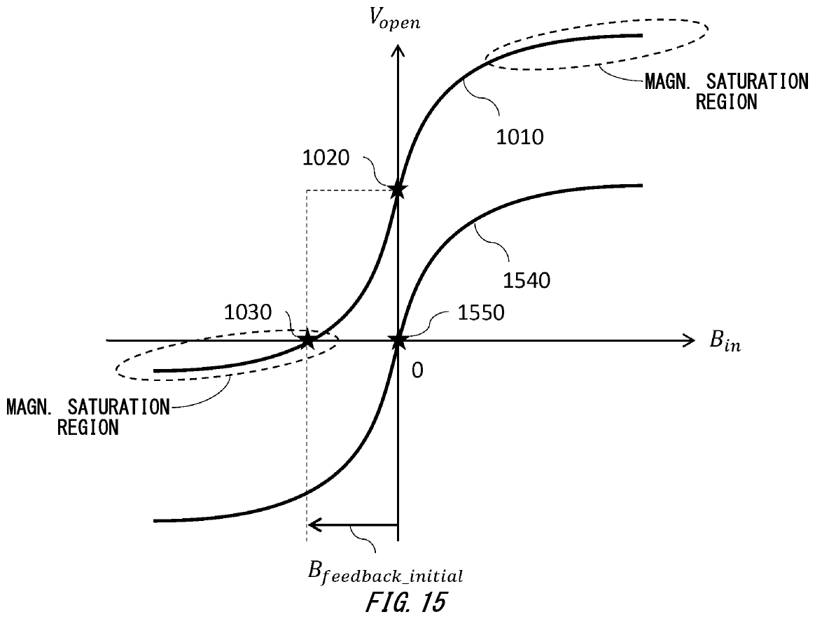

FIG. 15 illustrates characteristics of voltage Vopen generated corresponding to an input magnetic field Bin before and after magnetic operating point adjustment performed by the magnetic field measuring device 10 illustrated in FIG. 13 based on the flow illustrated in FIG. 14. Since explanations similar to those related to FIG. 10 apply to portions given the same symbols as those illustrated in FIG. 10, those explanations are omitted. A difference from FIG. 10 is that the magnetic field measuring device 10 performs magnetic operating point adjustment in the open loop.

Since, if the first switch 1310 switches the state of control from the closed-loop control to the open loop, the feedback magnetic field Bfeedback initial is no longer generated, the magnetic operating point of the first magnetoresistive element 112 and the second magnetoresistive element 114 transition from the point 1030 to the point 1020. In this state, for example, the adjusting unit 810 adjusts the reference voltage output by the reference voltage generating unit 510 so as to make the voltage Vopen 0 if there are no applied input magnetic fields input to the sensor unit 110. A curve 1540 illustrates characteristics of the voltage Vopen generated corresponding to the input magnetic field Bin to the sensor unit 110 after magnetic operating point adjustment based on the flow illustrated in FIG. 14. The magnetic field measuring device 10 illustrated in FIG. 13 performs magnetic operating point adjustment based on the flow illustrated in FIG. 14 to thereby be able to cause a transition of the magnetic operating point of the first magnetoresistive element 112 and the second magnetoresistive element 114 from the point 1020 to the point 1550. This point 1550 is a point where the voltage Vopen becomes 0 when there are no applied input magnetic fields Bin, and if the magnetic field measuring device 10 illustrated in FIG. 13 switches the state of control from the open loop to the closed loop in this state, and operates the first magnetoresistive element 112 and the second magnetoresistive element 114, the highest magnetic sensitivity can be attained.

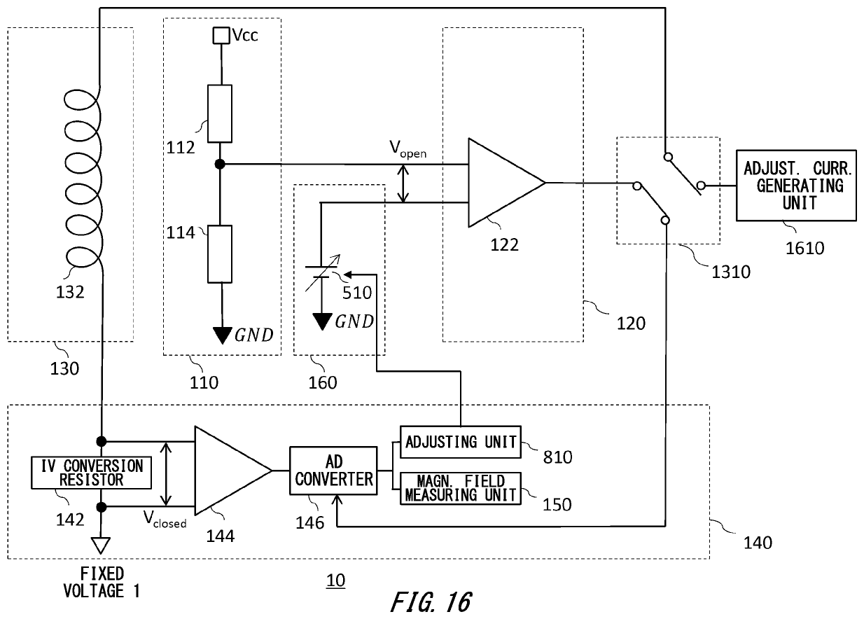

FIG. 16 illustrates the configuration of the magnetic field measuring device 10 according to a variant of the present embodiment, the magnetic field measuring device 10 being provided with the first switch 1310 and an adjustment current generating unit 1610. In FIG. 16, members having the same functions and configurations as those of members illustrated in FIG. 13 are given the same symbols, and also explanations related to matters other than differences therebetween are omitted hereinafter. The magnetic field measuring device 10 illustrated in this figure further includes the adjustment current generating unit 1610 in addition to the configurations of the magnetic field measuring device 10 illustrated in FIG. 13. The adjustment current generating unit 1610 generates an adjustment current Iadjust. In addition, the first switch 1310 of the magnetic field measuring device 10 in this figure can supply output of the feedback current generating unit 120 to the AD converter 146 if a feedback current is not supplied to the magnetic field generating unit 130, and also make the magnetic field generating unit 130 connected to the adjustment current generating unit 1610 to supply an adjustment current to the magnetic field generating unit 130. In this case, the adjusting unit 810 uses the output voltage of the sensor unit 110 in the state where an adjustment current is being supplied to the magnetic field generating unit 130 to adjust the reference voltage output by the reference voltage generating unit 510.

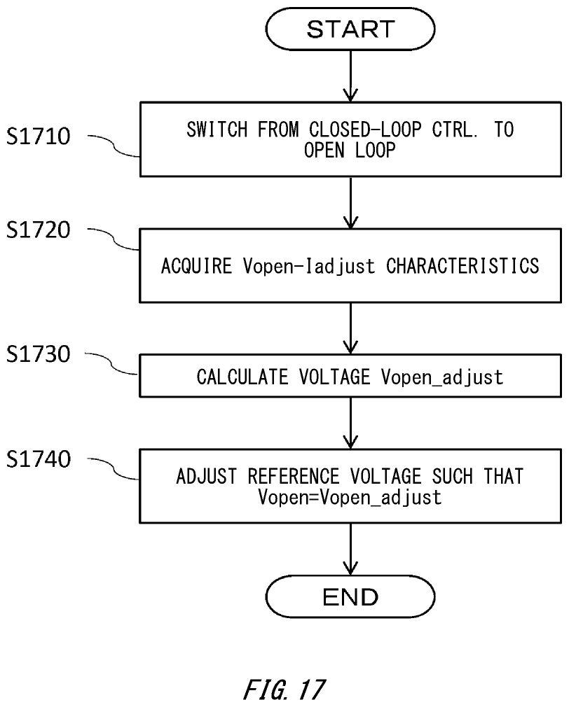

FIG. 17 illustrates a fourth exemplary flow of magnetic operating point adjustment performed by the magnetic field measuring device 10 illustrated in FIG. 16. At Step 1710, similar to Step 1410, the first switch 1310 switches the state of control from the closed-loop control to the open loop. In addition, the first switch 1310 supplies output of the feedback current generating unit 120 to the AD converter 146, and also make the magnetic field generating unit 130 connected to the adjustment current generating unit 1610 to supply an adjustment current to the magnetic field generating unit 130.

At Step 1720, the adjusting unit 810 sequentially acquires values of the voltage Vopen while changing the magnitude of the adjustment current Iadjust generated by the adjustment current generating unit 1610, and acquires characteristics of the voltage Vopen (Vopen-Iadjust characteristics) generated corresponding to the adjustment current Iadjust.

At Step 1730, the adjusting unit 810 calculates a voltage Vopen_adjust from the characteristics of the voltage Vopen generated corresponding to the adjustment current that are acquired at Step 1720. A method of calculating the voltage Vopen_adjust is described below.

At Step 1740, the adjusting unit 810 adjusts the reference voltage output by the reference voltage generating unit 510 based on the characteristics of the voltage Vopen which is the difference between the reference voltage and the output voltage of the sensor unit 110 generated corresponding to the adjustment current, and ends the process. For example, the adjusting unit 810 adjusts the reference voltage output by the reference voltage generating unit 510 such that the voltage Vopen becomes the voltage Vopen_adjust calculated at Step 1730.

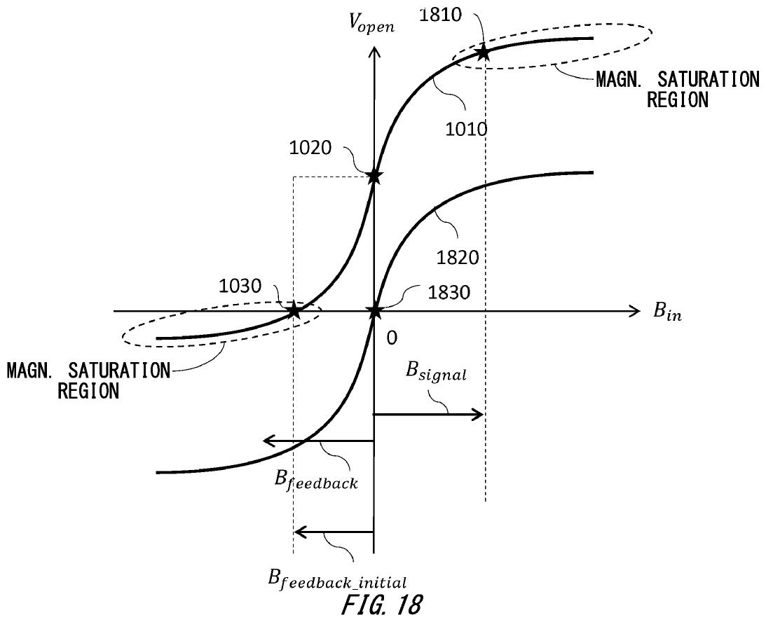

FIG. 18 illustrates characteristics of voltage Vopen generated corresponding to an input magnetic field Bin before and after magnetic operating point adjustment performed by the magnetic field measuring device 10 illustrated in FIG. 16 based on the flow illustrated in FIG. 17. Since explanations similar to those related to FIG. 15 apply to portions given the same symbols as those illustrated in FIG. 15, those explanations are omitted. A difference from FIG. 15 is that there is an applied input magnetic field Bin which has a finite value (defined as “Bsignal”).

The first switch 1310 switches the state of control from the closed-loop control to the open loop while the magnetic field generating unit 130 is generating the feedback magnetic fields Bfeedback_initial and Bfeedback based on the feedback current. Then, since the feedback magnetic fields Bfeedback_initial and Bfeedback are no longer generated, the magnetic operating point of the first magnetoresistive element 112 and the second magnetoresistive element 114 transitions to a point 1810 based on the magnetic field Bsignal. In this state, the adjusting unit 810 performs magnetic operating point adjustment based on the flow illustrated in FIG. 17 to adjust the reference voltage output by the reference voltage generating unit 510. A curve 1820 illustrates characteristics of voltage Vopen generated corresponding to an input magnetic field Bin to the sensor unit 110 after magnetic operating point adjustment performed by the magnetic field measuring device 10 illustrated in FIG. 16 based on the flow illustrated in FIG. 17. The magnetic field measuring device 10 illustrated in FIG. 16 performs magnetic operating point adjustment based on the flow illustrated in FIG. 17 to thereby be able to cause a transition of the magnetic operating point of the first magnetoresistive element 112 and the second magnetoresistive element 114 from the point 1810 to the point 1830. This point 1830 is a point where the voltage Vopen=Vopen_adjust, and if the magnetic field measuring device 10 illustrated in FIG. 16 switches the state of control from the open loop to the closed loop in this state, and operates the first magnetoresistive element 112 and the second magnetoresistive element 114, the highest magnetic sensitivity can be attained.

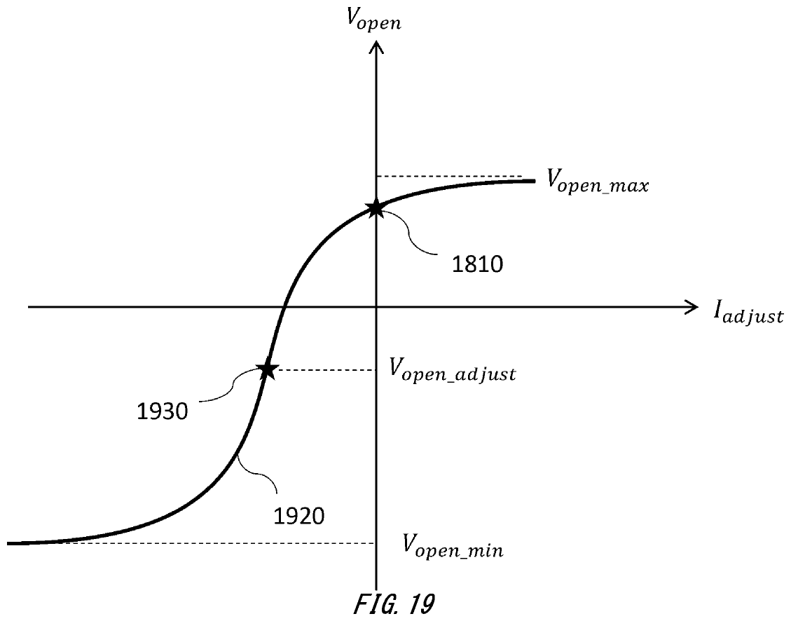

FIG. 19 illustrates characteristics of voltage Vopen generated corresponding to an adjustment current Iadjust used by the adjusting unit 810 in the magnetic field measuring device 10 illustrated in FIG. 16 for calculating the voltage Vopen_adjust. The adjusting unit 810 acquires characteristics of the voltage Vopen generated corresponding to the adjustment current Iadjust like those illustrated by a curve 1920, for example, through Step 1720 illustrated in FIG. 17. Then, the adjusting unit 810 calculates the voltage Vopen_adjust based on the curve 1920. For example, the adjusting unit 810 acquires, from the curve 1920, a voltage Vopen_max which is the maximum of the voltage Vopen, and a voltage Vopen_min which is the minimum of the voltage Vopen, and calculates the average value of the voltage Vopen_max and Vopen_min as the voltage Vopen_adjust.

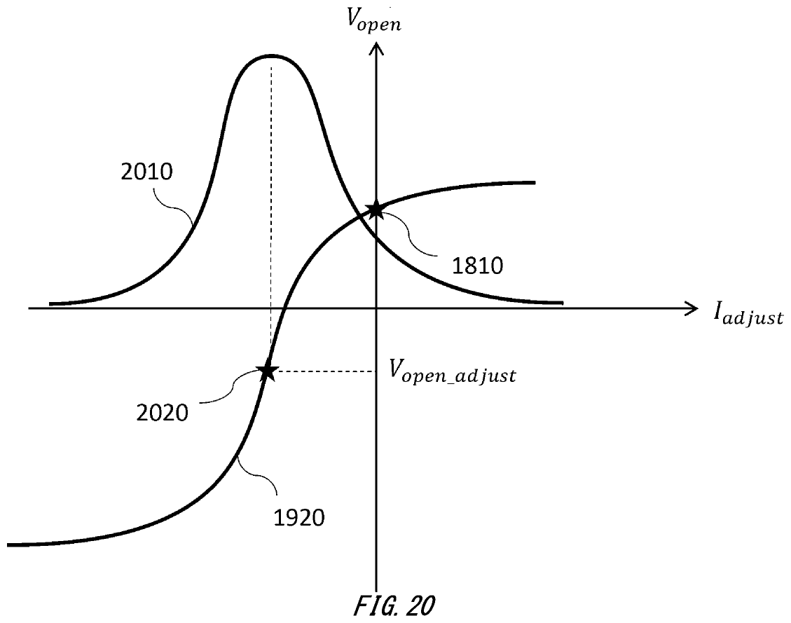

FIG. 20 illustrates characteristics of dVopen/dIadjust used by the adjusting unit 810 in the magnetic field measuring device 10 illustrated in FIG. 16 for calculating the voltage Vopen_adjust. The adjusting unit 810 differentiates the curve 1920 with respect to the adjustment current Iadjust to thereby obtain characteristics of dVopen/dIadjust in response to the adjustment current Iadjust like those illustrated in the curve 2010, for example. Then, the adjusting unit calculates the voltage Vopen at a point 2020 where dVopen/dIadjust becomes the maximum as the voltage Vopen_adjust.

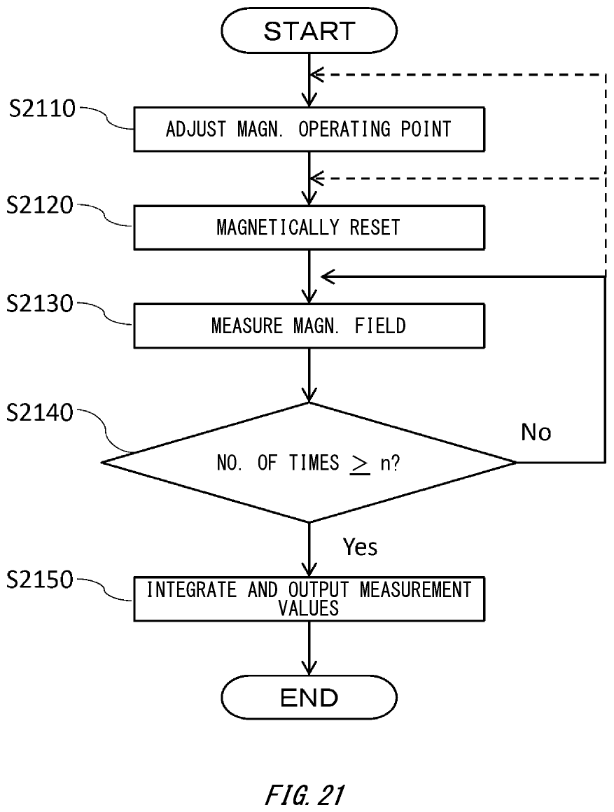

FIG. 21 illustrates a flow for the magnetic field measuring device 10 according to the present embodiment to measure a magnetic field. At Step 2110, the adjusting unit 810 adjusts the magnetic operating point of each magnetoresistive element provided in the sensor unit 110 according to a flow illustrated in at least any one of FIGS. 9, 11, 14 and 17, for example.

Next, at Step 2120, the magnetic resetting unit 160 magnetically resets each magnetoresistive element provided in the sensor unit 110 based on the flow illustrated in FIG. 2 or FIG. 7, for example.

Next, at Step 2130, the magnetic field measuring unit 150 measures a measurement-target magnetic field. Then, at Step 2140, the magnetic field measuring device 10 judges whether or not the number of times of magnetic field measurement has reached a predetermined number of times n (n is an integer equal to or larger than 1). If a result of the judgement indicates that the number of times of magnetic field measurement is smaller than the predetermined number of times n, the magnetic field measuring device 10 returns to the process at Step 2130, and continues the processes. On the other hand, if a result of the judgement indicates that the number of times of magnetic field measurement has reached the predetermined number of times n, the magnetic field measuring device 10 proceeds to the process at Step 2150, and at Step 2150, the magnetic field measuring unit 150 integrates measurement values obtained in a predetermined period, e.g., integrates n measurement values or performs another process, outputs a result of the integration, and ends the process. According to the present embodiment, the magnetic field measuring unit 150 can obtain more precise output by integrating n measurements, and outputs a result of the integration.

Note that although in the explanation above, the magnetic field measuring device 10 returns to the process at Step 2130 if the number of times of measurement is smaller than the predetermined number of times n at Step 2140, instead of this, it may return to the process at Step 2120 as illustrated by a dotted line in FIG. 21. That is, the magnetic field measuring device 10 may make the magnetic resetting unit 160 magnetically reset each magnetoresistive element provided in the sensor unit 110 every time the magnetic field measuring unit 150 performs magnetic field measurement. In addition, if the number of times of measurement is smaller than a predetermined number of times n at Step 2140, the magnetic field measuring device 10 may return to the process at Step 2110 as illustrated by the other dotted line in FIG. 21. That is, the magnetic field measuring device 10 may make the adjusting unit 810 adjust the magnetic operating point of each magnetoresistive element provided in the sensor unit 110, and make the magnetic resetting unit 160 magnetically reset each magnetoresistive element provided in the sensor unit 110 every time the magnetic field measuring unit 150 performs magnetic field measurement. By making the magnetic resetting unit 160 perform magnetic resetting every time, and making the adjusting unit 810 adjusting a magnetic operating point every time, it becomes possible to cause each magnetoresistive element provided in the sensor unit 110 to operate at a magnetic operating point where it can achieve a higher magnetic sensitivity. Note that the order of Step 2110 and Step 2120 may be reversed in the flow illustrated in this figure.

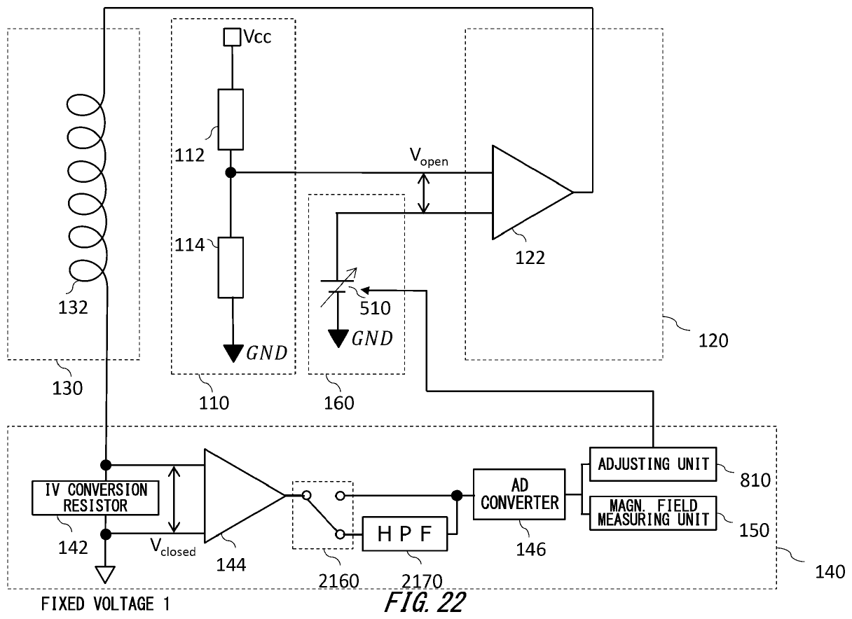

FIG. 22 illustrates the configuration of the magnetic field measuring device 10 according to a variant of the present embodiment, the magnetic field measuring device 10 being provided with a second switch 2160 and a high-pass filter 2170. In FIG. 22, members having the same functions and configurations as those of members illustrated in FIG. 8 are given the same symbols, and also explanations related to matters other than differences therebetween are omitted hereinafter. The magnetic field measuring device 10 illustrated in this figure includes the second switch 2160 and high-pass filter 2170 in addition to the configurations of the magnetic field measuring device 10 illustrated in FIG. 8. The second switch 2160 is provided between the second operational amplifier 144 and the AD converter 146, and switches whether to supply an output voltage VAMP of the second operational amplifier 144 directly to the AD converter 146 or to supply output of the second operational amplifier 144 to the AD converter 146 via the high-pass filter 2170. The high-pass filter 2170 allows passage therethrough of high-frequency components of the output voltage VAMP of the second operational amplifier 144, and supplies them to the AD converter 146.

The magnetic field measuring device 10 illustrated in this figure switches the second switch 2160 to supply the output voltage VAMP of the second operational amplifier 144 directly to the AD converter 146 bypassing the high-pass filter 2170 in an adjustment phase, and supplies the output VAMP of the second operational amplifier 144 to the AD converter 146 via the high-pass filter 2170 in a measurement phase. Thereby, if a measurement-target magnetic field is AC components in a measurement phase, unnecessary DC components can be blocked, and the magnetic field measuring unit 150 can measure the measurement-target magnetic field more precisely.

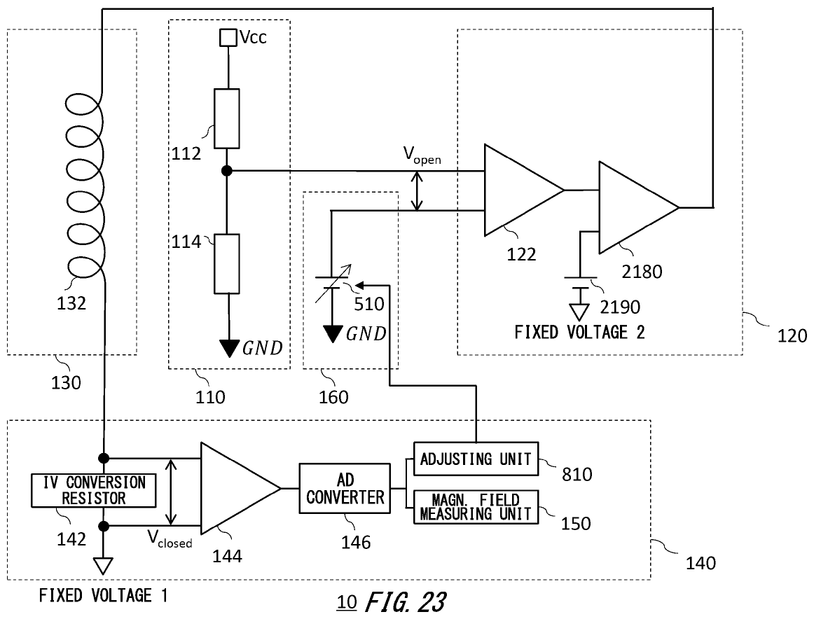

FIG. 23 illustrates the configuration of the magnetic field measuring device 10 according to a variant of the present embodiment, the magnetic field measuring device 10 being provided with a third operational amplifier 2180. In FIG. 23, members having the same functions and configurations as those of members illustrated in FIG. 8 are given the same symbols, and also explanations related to matters other than differences therebetween are omitted hereinafter. The magnetic field measuring device 10 illustrated in this figure further includes the third operational amplifier 2180 in addition to the configurations of the magnetic field measuring device 10 illustrated in FIG. 8, and the feedback current generating unit 120 is formed by using two or more operational amplifiers. The third operational amplifier 2180 has one differential input terminal connected to output of the first operational amplifier 122, and another differential input terminal connected to the fixed voltage source 2190. The feedback current generating unit 120 illustrated in this figure may make the first operational amplifier 122 output the voltage Vopen which is the difference between the reference voltage and the output voltage of the sensor unit 110, and make the third operational amplifier 2180 generate a feedback current based on the difference between the voltage Vopen and the fixed voltage 2. Here, the same voltage may be set for the fixed voltage 1 and the fixed voltage 2.

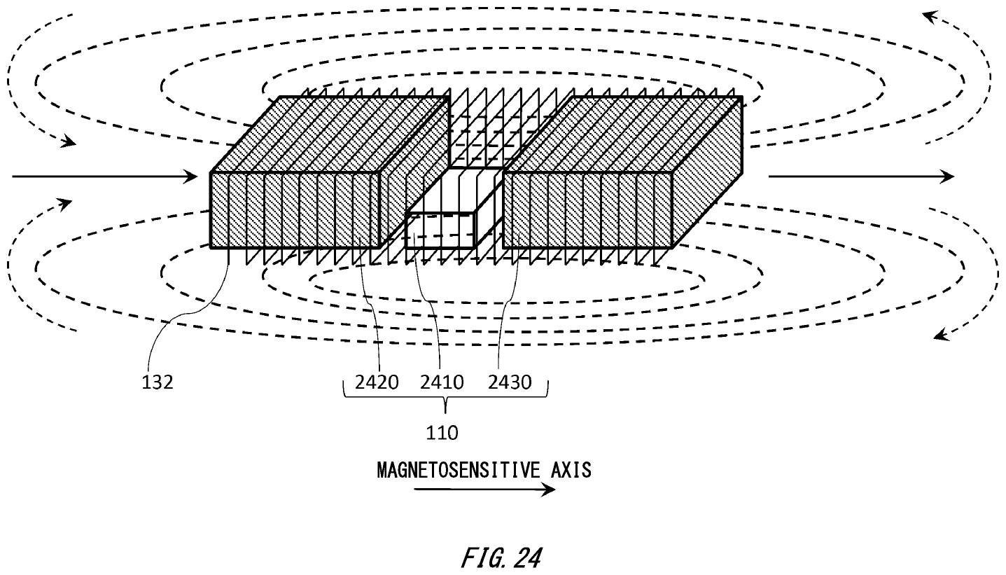

FIG. 24 illustrates a specific example of the sensor unit 110 according to the present embodiment. The sensor unit 110 has a magnetoresistive element 2410, and magnetic flux concentrators 2420 and 2430 (the magnetic flux concentrator 2420 and the magnetic flux concentrator 2430 are collectively referred to as a “magnetic flux concentrating unit”) that are arranged at both ends of the magnetoresistive element 2410. Note that, here, the magnetoresistive element 2410 may be at least one of the first magnetoresistive element 112, the second magnetoresistive element 114, the third magnetoresistive element 116, and the fourth magnetoresistive element 118, for example. The magnetic flux concentrators 2420 and 2430 are arranged at both ends of the magnetoresistive element 2410 so as to sandwich the magnetoresistive element 2410. That is, the sensor unit 110 includes the magnetic flux concentrating unit arranged adjacent to the magnetoresistive element 2410. In this figure, the magnetic flux concentrator 2420 is provided on the negative side of the magnetoresistive element 2410 along the magnetosensitive axis, and the magnetic flux concentrator 2430 is provided on the positive side of the magnetoresistive element 2410 along the magnetosensitive axis. Note that, here, the magnetosensitive axis may lie along the direction of magnetization that is fixed by a magnetization fixed layer forming the magnetoresistive element 2410. In addition, if a magnetic field is input from the negative side of the magnetosensitive axis toward its positive side, the resistance of the magnetoresistive element 2410 may increase or decrease. The magnetic flux concentrators 2420 and 2430 are formed of a material having high magnetic permeability such as Permalloy, for example. Then, if the sensor unit 110 is configured in the manner as illustrated in the present specific example, the coil 132 is wound to surround cross-sections of the magnetoresistive element 2410, and the magnetic flux concentrators 2420 and 2430 arranged at both ends of the magnetoresistive element 2410. That is, the feedback current generating unit 120 is formed to surround the magnetoresistive element 2410 and the magnetic flux concentrating unit. In addition, if the sensor unit 110 has a plurality of magnetoresistive elements 2410, it may have a plurality of sets of a magnetoresistive element and magnetic flux concentrators arranged at both ends thereof. In this case, one coil 132 may be wound to surround a set of a magnetoresistive element and magnetic flux concentrators arranged at both ends thereof.

If such a sensor unit 110 receives a magnetic field from the negative side of the magnetosensitive axis to its positive side, the magnetic flux concentrators 2420 and 2430 formed of a material having high magnetic permeability are magnetized to thereby generate a magnetic flux distribution like the one indicated by broken lines in this figure. Then, magnetic fluxes generated by magnetization of the magnetic flux concentrators 2420 and 2430 pass through the position of the magnetoresistive element 2410 sandwiched between the two magnetic flux concentrators 2420 and 2430. Because of this, the magnetic flux density at the position of the magnetoresistive element 2410 can be significantly increased by arranging the magnetic flux concentrators 2420 and 2430. In addition, as in the present specific example, by using the magnetoresistive element 2410 arranged at a position with a small area sandwiched by the magnetic flux concentrators 2420 and 2430 to perform sampling of the spatial distribution of a magnetic field, it becomes possible to make a sampling point in the space clear.

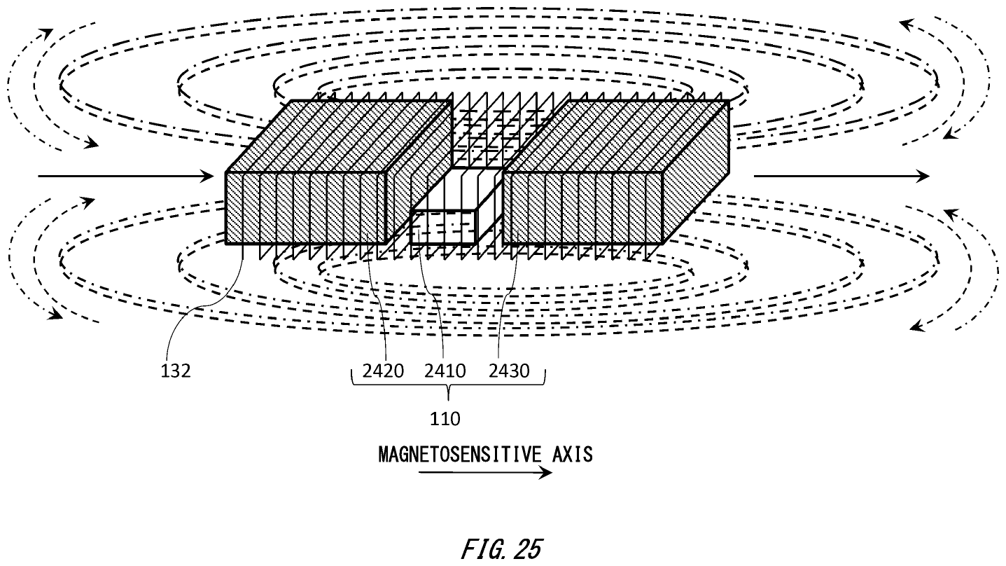

FIG. 25 illustrates a magnetic flux distribution observed when a feedback magnetic field is generated to the sensor unit 110 according to the present specific example. In FIG. 25, members having the same functions and configurations as those of members illustrated in FIG. 24 are given the same symbols, and also explanations related to matters other than differences therebetween are omitted hereinafter. If a feedback current is supplied to the coil 132 in the sensor unit 110 according to the present specific example, the coil 132 generates a feedback magnetic field to thereby generate a magnetic flux distribution like the one illustrated by alternate long and short dash lines in this figure. Magnetic fluxes generated by this feedback magnetic field are spatially distributed to cancel out the spatial distribution of a magnetic field input to the magnetoresistive element 2410 and magnetically amplified by the magnetic flux concentrators 2420 and 2430. Because of this, as illustrated in the present specific example, if the magnetic flux concentrators 2420 and 2430 are arranged at both ends of the magnetoresistive element 2410, the sensor unit 110 can accurately cancel out the magnetic field distribution at the position of the magnetoresistive element 2410 by using the feedback magnetic field; as a result, it becomes possible to realize a sensor with high linearity between an input magnetic field and an output voltage.

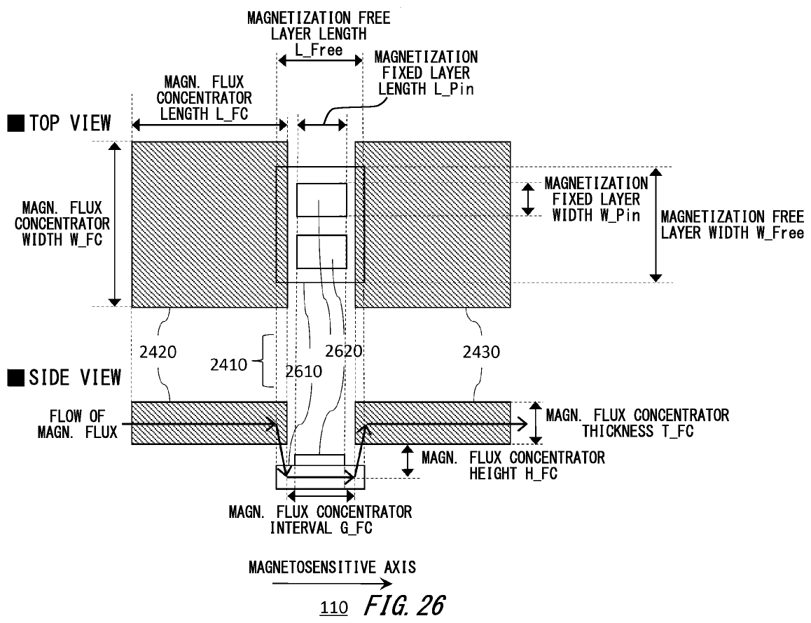

FIG. 26 illustrates an exemplary configuration of the sensor unit 110 according to the present specific example. In FIG. 26, members having the same functions and configurations as those of members illustrated in FIG. 24 are given the same symbols, and also explanations related to matters other than differences therebetween are omitted hereinafter. In this figure, the magnetoresistive element 2410 has a magnetization free layer 2610 and a magnetization fixed layer 2620. Typically, the magnetoresistive element 2410 has a structure in which two ferromagnetic layers sandwich an insulator thin-film layer. The magnetization free layer 2610 is a layer which is one of the two ferromagnetic layers, and has a magnetization direction that changes depending on an external magnetic field. In addition, the magnetization fixed layer 2620 is a layer which is the other of the two ferromagnetic layers, and has a magnetization direction which does not change even if it receives an external magnetic field. For example, the magnetoresistive element 2410 has the magnetization free layer 2610, a non-magnetic layer, and the magnetization fixed layer 2620 that are stacked on a substrate in this order.

In the present specific example, the magnetoresistive element 2410 is a magnetoresistive element having a so-called bottom free structure in which the magnetization free layer 2610 is arranged at a lower portion, and the magnetization fixed layer 2620 is arranged at an upper portion of the magnetization free layer 2610 via an insulator thin-film layer (not illustrated). Since a magnetoresistive element with the bottom free structure allows the magnetization free layer 2610 to be formed to have a relatively wide area, a high magnetic sensitivity can be attained. Note that, in the magnetoresistive element 2410, when seen from above, the area of the magnetization fixed layer 2620 is smaller than the area of the magnetization free layer 2610, and the magnetosensitive area is determined based on the area of the magnetization fixed layer 2620.

In addition, in the present specific example, the sensor unit 110 has the magnetic flux concentrators 2420 and 2430 that are arranged at both ends of the magnetoresistive element 2410 so as to sandwich the magnetoresistive element 2410 at the middle of their interval, via an insulation layer (not illustrated) at an upper portion of the magnetoresistive element 2410. Thereby, the magnetoresistive element 2410 is arranged in a small space sandwiched by the magnetic flux concentrators 2420 and 2430.

Here, in this figure, the length of the magnetization free layer 2610 along the magnetosensitive axis direction is defined as a magnetization free layer length L_Free. In addition, the length of the magnetization free layer 2610 along an axis perpendicular to the magnetosensitive axis direction when seen from above is defined as a magnetization free layer width W_Free. In addition, the length of the magnetization fixed layer 2620 along the magnetosensitive axis direction is defined as a magnetization fixed layer length L_Pin. In addition, the length of the magnetization fixed layer 2620 along an axis perpendicular to the magnetosensitive axis direction when seen from above is defined as a magnetization fixed layer width W_Pin. In addition, the length from one outer end of a magnetic flux concentrator to one outer end of the magnetization free layer along the magnetosensitive axis direction (in this figure, the length from the left end of the magnetic flux concentrator 2420 to its right end along the magnetosensitive axis direction, and the length from the right end of the magnetic flux concentrator 2430 to its left end along the magnetosensitive axis direction) is defined as a magnetic flux concentrator length L_FC. In addition, the length of the magnetic flux concentrator along an axis perpendicular to the magnetosensitive axis direction when seen from above is defined as a magnetic flux concentrator width W_FC. In addition, the length of the magnetic flux concentrator along an axis perpendicular to the magnetosensitive axis direction when seen from side is defined as a magnetic flux concentrator thickness T_FC. In addition, the interval between the two magnetic flux concentrators 2420 and 2430 along the magnetosensitive axis direction (in this figure, the length from the right end of the magnetic flux concentrator 2420 to the left end of the magnetic flux concentrator 2430 along the magnetosensitive axis direction) is defined as a magnetic flux concentrator interval G FC. In addition, an interval from the center of the magnetization free layer 2610 in its thickness direction to the bottom surface of the magnetic flux concentrator along an axis perpendicular to the magnetosensitive axis direction when seen from side is defined as a magnetic flux concentrator height H_FC.

Various embodiments of the present invention may be described with reference to flowcharts and block diagrams whose blocks may represent (1) steps of processes in which operations are performed or (2) sections of apparatuses responsible for performing operations. Certain steps and sections may be implemented by dedicated circuitry, programmable circuitry supplied with computer-readable instructions stored on computer-readable media, and/or processors supplied with computer-readable instructions stored on computer-readable media. Dedicated circuitry may include digital and/or analog hardware circuits and may include integrated circuits (IC) and/or discrete circuits. Programmable circuitry may include reconfigurable hardware circuits comprising logical AND, OR , XOR, NAND, NOR, and other logical operations, flip-flops, registers, memory elements, etc., such as field-programmable gate arrays (FPGA), programmable logic arrays (PLA), etc.

Computer-readable media may include any tangible device that can store instructions for execution by a suitable device, such that the computer-readable medium having instructions stored therein comprises an article of manufacture including instructions which can be executed to create means for performing operations specified in the flowcharts or block diagrams. Examples of computer-readable media may include an electronic storage medium, a magnetic storage medium, an optical storage medium, an electromagnetic storage medium, a semiconductor storage medium, etc. More specific examples of computer-readable media may include a floppy disk, a diskette, a hard disk, a random access memory (RAM), a read-only memory (ROM), an erasable programmable read-only memory (EPROM or Flash memory), an electrically erasable programmable read-only memory (EEPROM), a static random access memory (SRAM), a compact disc read-only memory (CD-ROM), a digital versatile disk (DVD), a BLU-RAY® disc, a memory stick, an integrated circuit card, etc.

Computer-readable instructions may include assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, JAVA (registered trademark), C++, etc., and conventional procedural programming languages, such as the “C” programming language or similar programming languages.

Computer-readable instructions may be provided to a processor of a general purpose computer, special purpose computer, or other programmable data processing apparatus, or to programmable circuitry, locally or via a local area network (LAN), wide area network (WAN) such as the Internet, etc., to execute the computer-readable instructions to create means for performing operations specified in the flowcharts or block diagrams. Examples of processors include computer processors, processing units, microprocessors, digital signal processors, controllers, microcontrollers, etc.

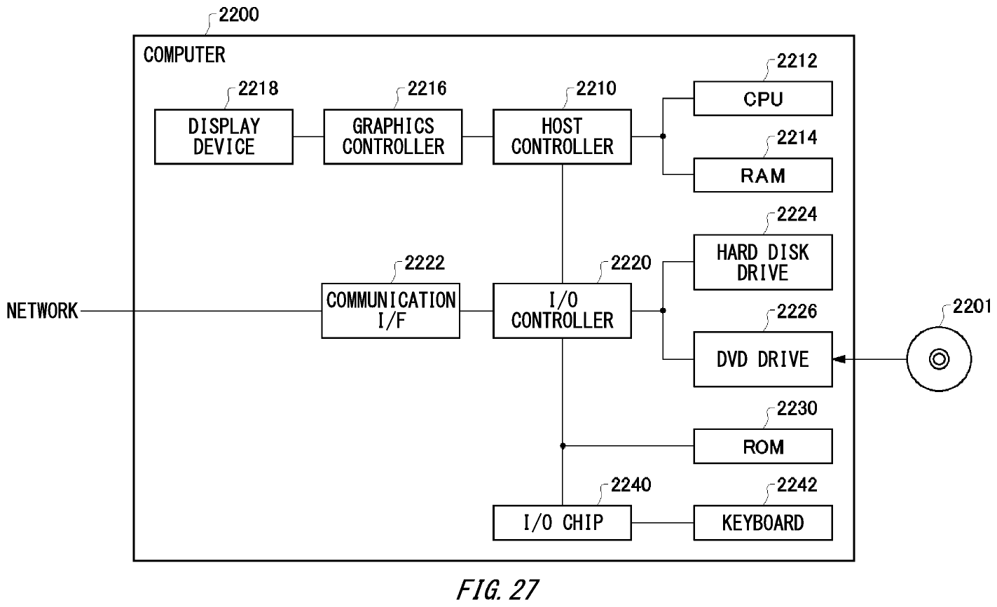

FIG. 27 shows an example of a computer 2200 in which aspects of the present invention may be wholly or partly embodied. A program that is installed in the computer 2200 can cause the computer 2200 to function as or perform operations associated with apparatuses of the embodiments of the present invention or one or more sections thereof, and/or cause the computer 2200 to perform processes of the embodiments of the present invention or steps thereof. Such a program may be executed by the CPU 2212 to cause the computer 2200 to perform certain operations associated with some or all of the blocks of flowcharts and block diagrams described herein.

The computer 2200 according to the present embodiment includes a CPU 2212, a RAM 2214, a graphics controller 2216, and a display device 2218, which are mutually connected by a host controller 2210. The computer 2200 also includes input/output units such as a communication interface 2222, a hard disk drive 2224, a DVD-ROM drive 2226 and an IC card drive, which are connected to the host controller 2210 via an input/output controller 2220. The computer also includes legacy input/output units such as a ROM 2230 and a keyboard 2242, which are connected to the input/output controller 2220 through an input/output chip 2240.

The CPU 2212 operates according to programs stored in the ROM 2230 and the RAM 2214, thereby controlling each unit. The graphics controller 2216 obtains image data generated by the CPU 2212 on a frame buffer or the like provided in the RAM 2214 or in itself, and causes the image data to be displayed on the display device 2218.

The communication interface 2222 communicates with other electronic devices via a network. The hard disk drive 2224 stores programs and data used by the CPU 2212 within the computer 2200. The DVD-ROM drive 2226 reads the programs or the data from the DVD-ROM 2201, and provides the hard disk drive 2224 with the programs or the data via the RAM 2214. The IC card drive reads programs and data from an IC card, and/or writes programs and data into the IC card.

The ROM 2230 stores therein a boot program or the like executed by the computer 2200 at the time of activation, and/or a program depending on the hardware of the computer 2200. The input/output chip 2240 may also connect various input/output units via a parallel port, a serial port, a keyboard port, a mouse port, and the like to the input/output controller 2220.

A program is provided by computer readable media such as the DVD-ROM 2201 or the IC card. The program is read from the computer readable media, installed into the hard disk drive 2224, RAM 2214, or ROM 2230, which are also examples of computer readable media, and executed by the CPU 2212. The information processing described in these programs is read into the computer 2200, resulting in cooperation between a program and the above-mentioned various types of hardware resources. An apparatus or method may be constituted by realizing the operation or processing of information in accordance with the usage of the computer 2200.

For example, when communication is performed between the computer 2200 and an external device, the CPU 2212 may execute a communication program loaded onto the RAM 2214 to instruct communication processing to the communication interface 2222, based on the processing described in the communication program. The communication interface 2222, under control of the CPU 2212, reads transmission data stored on a transmission buffering region provided in a recording medium such as the RAM 2214, the hard disk drive 2224, the DVD-ROM 2201, or the IC card, and transmits the read transmission data to a network or writes reception data received from a network to a reception buffering region or the like provided on the recording medium.

In addition, the CPU 2212 may cause all or a necessary portion of a file or a database to be read into the RAM 2214, the file or the database having been stored in an external recording medium such as the hard disk drive 2224, the DVD-ROM drive 2226 (DVD-ROM 2201), the IC card, etc., The CPU 2212 may then write back the processed data to the external recording medium.

Various types of information, such as various types of programs, data, tables, and databases, may be stored in the recording medium to undergo information processing. The CPU 2212 may perform various types of processing on the data read from the RAM 2214, which includes various types of operations, processing of information, condition judging, conditional branch, unconditional branch, search/replace of information, etc., as described throughout this disclosure and designated by an instruction sequence of programs, and writes the result back to the RAM 2214. In addition, the CPU 2212 may search for information in a file, a database, etc., in the recording medium. For example, when a plurality of entries, each having an attribute value of a first attribute associated with an attribute value of a second attribute, are stored in the recording medium, the CPU 2212 may search for an entry matching the condition whose attribute value of the first attribute is designated, from among the plurality of entries, and read the attribute value of the second attribute stored in the entry, thereby obtaining the attribute value of the second attribute associated with the first attribute satisfying the predetermined condition.

The above-explained program or software modules may be stored in the computer readable media on or near the computer 2200. In addition, a recording medium such as a hard disk or a RAM provided in a server system connected to a dedicated communication network or the Internet can be used as the computer readable media, thereby providing the program to the computer 2200 via the network.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A magnetic field measuring device comprising:
a sensor unit that has at least one magnetoresistive element;
a magnetic field generating unit that generates a magnetic field to be applied to the sensor unit;
a feedback current generating unit that supplies, based on an output voltage of the sensor unit, the magnetic field generating unit with a feedback current that generates a feedback magnetic field to diminish an input magnetic field input to the sensor unit;
a magnetic field measuring unit that outputs a measurement value corresponding to the feedback current; and
a magnetic resetting unit that makes the magnetic field generating unit generate a reset magnetic field that magnetically saturates the magnetoresistive element.

2. The magnetic field measuring device according to claim 1, wherein
in a reset phase, the magnetic resetting unit makes the magnetic field generating unit generate the reset magnetic field, and
in a measurement phase, the magnetic field measuring unit outputs a measurement corresponding to the feedback current generated for a measurement-target magnetic field.

3. The magnetic field measuring device according to claim 1, wherein
the magnetic resetting unit has a reset current supply unit that supplies a reset current to the magnetic field generating unit, and
the reset current supply unit supplies the reset current to the magnetic field generating unit, and makes the magnetic field generating unit generate the reset magnetic field.

4. The magnetic field measuring device according to claim 3, further comprising a switching unit that switches whether to or not to supply the feedback current to the magnetic field generating unit, wherein
the reset current supply unit supplies the reset current to the magnetic field generating unit while the feedback current is not being supplied to the magnetic field generating unit.

5. The magnetic field measuring device according to claim 1, wherein
the magnetic resetting unit has a reference voltage generating unit that outputs a reference voltage,
the feedback current generating unit supplies, to the magnetic field generating unit, the feedback current corresponding to a difference between the output voltage of the sensor unit and the reference voltage, and
the reference voltage generating unit changes the reference voltage to be output, and makes the magnetic field generating unit generate the reset magnetic field.

6. The magnetic field measuring device according to claim 5, wherein
the reference voltage generating unit has at least one variable resistor, and
the reference voltage generating unit changes a resistance value of the variable resistor, and makes the magnetic field generating unit generate the reset magnetic field.

7. The magnetic field measuring device according to claim 5, wherein an output voltage range of the reference voltage generating unit is larger than an output voltage range of the sensor unit.

8. The magnetic field measuring device according to claim 5, further comprising an adjusting unit that uses the output voltage of the sensor unit to adjust the reference voltage.

9. The magnetic field measuring device according to claim 8, wherein the adjusting unit adjusts the reference voltage based on the feedback current.

10. The magnetic field measuring device according to claim 8, wherein the adjusting unit adjusts the reference voltage based on a difference between the output voltage of the sensor unit and the reference voltage.

11. The magnetic field measuring device according to claim 1, wherein, after making the magnetic field generating unit generate the reset magnetic field to magnetically saturate the magnetoresistive element, the magnetic resetting unit gradually weakens a strength of the reset magnetic field.

12. The magnetic field measuring device according to claim 1, wherein the magnetic field measuring unit integrates measurement values obtained in a predetermined period, and outputs the integrated measurements.

13. The magnetic field measuring device according to claim 1, further comprising a high-pass filter that allows passage therethrough of a high-frequency component of a measurement value output by the magnetic field measuring unit.

14. The magnetic field measuring device according to claim 1, wherein the feedback current generating unit is formed by using two or more operational amplifiers.

15. The magnetic field measuring device according to claim 1, wherein the sensor unit includes a magnetic flux concentrating unit arranged adjacent to the magnetoresistive element, and the feedback current generating unit is formed to surround the magnetoresistive element and the magnetic flux concentrating unit.

16. The magnetic field measuring device according to claim 1, wherein the magnetoresistive element includes a magnetization free layer, a non-magnetic layer, and a magnetization fixed layer that are stacked on a substrate in this order, and, when seen from above, the area of the magnetization fixed layer is smaller than the area of the magnetization free layer, and a magnetosensitive area is determined based on the area of the magnetization fixed layer.

17. The magnetic field measuring device according to claim 1, wherein
the sensor unit has a first magnetoresistive element and a second magnetoresistive element that are connected in series and have opposite polarity to each other, and
a voltage across the first magnetoresistive element and the second magnetoresistive element is output.

18. A magnetic field measurement method by which a magnetic field measuring device measures a magnetic field, the magnetic field measurement method comprising:
supplying, by the magnetic field measuring device and based on an output voltage of a sensor unit having at least one magnetoresistive element, a magnetic field generating unit that generates a magnetic field to be applied to the sensor unit with a feedback current that generates a feedback magnetic field to diminish an input magnetic field to the sensor unit;
outputting a measurement value corresponding to the feedback current; and
making the magnetic field generating unit generate a reset magnetic field to magnetically saturate the magnetoresistive element.

19. A recording medium having recorded thereon a magnetic field measurement program that, when executed by a computer, makes the computer function as:
a feedback current generating unit that supplies, based on an output voltage of a sensor unit having at least one magnetoresistive element, a magnetic field generating unit that generates a magnetic field to be applied to the sensor unit with a feedback current that generates a feedback magnetic field to diminish an input magnetic field to the sensor unit;
a magnetic field measuring unit that outputs a measurement value corresponding to the feedback current; and
a magnetic resetting unit that makes the magnetic field generating unit generate a reset magnetic field to magnetically saturate the magnetoresistive element.
